(19) United States
(12) Patent Application Publication
(10) Pub. No.: US 2026/0114125 A1
(43) Pub. Date: Apr. 23, 2026

(54) ORGANIC LIGHT-EMITTING UNIT, DISPLAY DEVICE, ELECTRONIC DEVICE, IN-VEHICLE DISPLAY, AND VEHICLE

(71) Applicant: Tianma Japan, Ltd., Kawasaki (JP)

(72) Inventors: Keita HAMADA, Kawasaki (JP); Shigeru MORI, Kawasaki (JP)

(73) Assignee: Tianma Japan, Ltd., Kawasaki (JP)

(21) Appl. No.: 19/357,739

(22) Filed: Oct. 14, 2025

(30) Foreign Application Priority Data
Oct. 21, 2024 (JP) 2024-185289

(51) Int. Cl. H10K 50/852

(52) U.S. Cl. CPC H10K 50/852

(57) ABSTRACT

The present disclosure discloses an organic light-emitting unit, a display device, an electronic device, an in-vehicle display, and a vehicle. The organic light-emitting unit includes, between an anode electrode and a cathode electrode opposed to each other, a light-emitting mechanism having a light-emitting layer, and an interference reflector. The interference reflector is disposed in contact with the anode electrode. The interference reflector includes p-type low refractive-index layers as first charge generating layers having a first type of conductivity and a first refractive index, and n-type high refractive-index layers as second charge generating layers having a second type of conductivity and a second refractive index. In the interference reflector, the p-type low refractive-index layers and the n-type high refractive-index layers are alternately stacked on each other.

### CROSS-REFERENCE TO RELATED APPLICATIONS

This application claims the benefit of Japanese Patent Application No. 2024-185289, filed on Oct. 21, 2024, the entire disclosure of which is incorporated by reference herein.

### FIELD OF THE INVENTION

This application relates to an organic light-emitting unit, a display device, an electronic device, an in-vehicle display, and a vehicle.

### BACKGROUND OF THE INVENTION

Some organic light-emitting units made of organic light-emitting materials have been known designed to have improved luminous efficiency and enhanced monochromaticity using the microcavity effect. FIG. 30A illustrates an element structure of an organic light-emitting unit 501. This element structure includes an anode electrode 511 and a cathode electrode 512 opposed to each other on a circuit board 510 that form microcavities. In the case where the anode electrode 511 is a reflective electrode made of a metal electrode and the cathode electrode 512 is a translucent electrode, the emission intensity varies depending on a distance DA between the anode electrode 511 and the center of a light-emitting layer 513 and a distance DB between the cathode electrode 512 and the center of the light-emitting layer 513. FIG. 30B illustrates zones Z01, Z02, and Z03 revealed by optical simulations, where the distances DA and DB provide enhanced microcavity effect. FIG. 30B illustrates results of optical simulations in the case of a light dominant wavelength of 460 nm. The simulation results reflecting the microcavity effect alone demonstrate that the emission intensity has the highest first peak in the zone Z01 and the second highest second peaks nearly equal to each other in the zones Z02 and Z03. In contrast, the experiment results illustrated in FIG. 31 demonstrate that the emission intensity has a peak in the zone Z01 represented by the curve CU11, a peak in the zone Z02 represented by the curve CU12, and a peak in the zone Z03 represented by the curve CU13.

Specifically, the peak of emission intensity represented by the curve CU12 is higher than the peak of emission intensity represented by the curve CU11 illustrated in FIG. 31. The peak of emission intensity represented by the curve CU13 is higher than the peak of emission intensity represented by the curve CU12. These experiment results are inconsistent with the simulation results reflecting the microcavity effect alone.

The optical simulations for the organic light-emitting unit 501, including a reflective metal electrode made of a metal, such as silver (Ag), as the anode electrode 511, must consider an optical loss called surface plasmon loss. When the optical simulations reflecting not only the microcavity effect but also the optical loss in contrast to the results illustrated in FIG. 30B, the peak of emission intensity in the zone Z03 is higher than the peak of emission intensity in the zone Z02. Also, the peak of emission intensity in the zone Z02 is higher than the peak of emission intensity in the zone Z01. These results of optical simulations are consistent with the experiment results illustrated in FIG. 31.

Surface plasmons are oscillations of electrons that propagate along the surface of a conductor. The organic light-emitting unit 501 including a metal electrode as the anode electrode 511 is susceptible to an optical loss resulting from coupling of the light emitted from emissive dipoles due to molecular excitons in the light-emitting layer with the electron oscillations in the reflective electrode. In general, optical simulations can calculate an external quantum efficiency by multiplying a carrier balance, an exciton generation rate, a radiative quantum efficiency, and a light extraction efficiency. The calculation in the optical simulations can reflect an optical loss if the radiative quantum efficiency is based on a Purcell factor.

Top-emission organic light-emitting diode (OLED) displays, each including the organic light-emitting unit 501 designed to extract light from the side adjacent to the cathode electrode 512, have an elongated distance DA from the anode electrode 511 to the center of the light-emitting layer 513, to reduce the optical loss. Some top-emission OLED displays have a tandem structure including multiple light-emitting layers, such as two light-emitting layers 513A and 513B illustrated in FIG. 32, between the anode electrode 511 and the cathode electrode 512 opposed to each other, to improve the luminance and increase the life-span. The tandem structure having the same total film thickness as a single structure, however, has a shorter distance between the lower light-emitting layer 513A and the anode electrode 511 serving as the reflective electrode. The tandem structure thus fails to achieve a luminous efficiency twice as high as the luminous efficiency of a single structure, in the case of green or blue light. The reflective electrode serving as the anode electrode 511 requires an alternative structure to improve the luminous efficiency.

Unexamined Japanese Patent Application Publication No. 2007-317591 discloses a dielectric mirror functioning as an optical resonator that enhances light at specific wavelengths. Unexamined Japanese Patent Application Publication No. 2023-4940 discloses a light-emitting device including a light-emitting layer and low refractive-index layers containing organic compounds. U.S. Patent Application Publication No. 2015/0041768 discloses an optical member fabricated by repetitively and alternately stacking high refractive-index layers and low refractive-index layers on each other.

The structures disclosed in Unexamined Japanese Patent Application Publication No. 2007-317591 and U.S. Patent Application Publication No. 2015/0041768 each include a reflection mechanism below a transparent anode electrode, and a transparent conductive film having a relatively high sheet resistance, which may adversely affect the display properties. The structures, having a film thickness increased to lower the resistance of the electrode of the transparent conductive film, cause absorption of a larger amount of light at short wavelengths, which may impair the luminous efficiency of blue light. The technique disclosed in Unexamined Japanese Patent Application Publication No. 2023-4940 is intended to enhance the monochromaticity by means of interference. This technique, however, requires a stack of multiple charge transport layers to increase the reflection factor, and thus inevitably raises the driving voltage. The technique may thus encounter challenges in adjusting the carrier balance due to carrier deficiency.

### SUMMARY OF THE INVENTION

An organic light-emitting unit according to a first aspect of the present disclosure includes: a first electrode and a second electrode opposed to each other; and organic compound layers disposed between the first electrode and the second electrode, and including at least a light-emitting layer and an interference reflector. The interference reflector includes first charge generating layers having a first type of conductivity and a first refractive index and second charge generating layers having a second type of conductivity and a second refractive index that are alternately stacked on each other. The interference reflector is disposed in contact with the first electrode or the second electrode.

A display device according to a second aspect of the present disclosure includes the organic light-emitting unit according to the first aspect.

An in-vehicle display according to a third aspect of the present disclosure includes the display device according to the second aspect.

An electronic device according to a fourth aspect of the present disclosure includes the display device according to the second aspect.

A vehicle according to a fifth aspect of the present disclosure includes the in-vehicle display according to the third aspect.

It is to be understood that both the foregoing general description and the following detailed description are exemplary and explanatory and are not restrictive of this disclosure.

### BRIEF DESCRIPTION OF DRAWINGS

A more complete understanding of this application can be obtained when the following detailed description is considered in conjunction with the following drawings, in which:

FIG. 1 is a schematic diagram illustrating a first exemplary structure of an organic light-emitting unit according to Embodiment 1;

FIG. 2 is a curve graph illustrating exemplary simulations of reflection factors;

FIG. 3 is a curve graph illustrating exemplary simulations of reflection factors;

FIG. 4 is a curve graph illustrating exemplary simulations of reflection factors;

FIG. 5 is a sectional view of the light-emitting units and driving TFTs;

FIG. 6A is a circuit diagram illustrating a first pixel circuit;

FIG. 6B is a circuit diagram illustrating a second pixel circuit;

FIG. 7 illustrates bar graphs for comparison of optical losses and luminous efficiencies;

FIG. 8A is a schematic diagram illustrating an exemplary structure of a light extraction layer provided with a polarizing plate;

FIG. 8B is a schematic diagram illustrating an exemplary structure of a light extraction layer provided with a color filter;

FIG. 9 is a schematic diagram illustrating an exemplary structure of a microlens array;

FIG. 10 illustrates a bar graph for comparison of the percentages of losses;

FIG. 11 illustrates a curve graph for comparison of the current-voltage characteristics between organic material layers;

FIG. 12 illustrates energy states of the individual layers of the organic light-emitting unit;

FIG. 13 is a polygonal line graph illustrating a relationship between a driving voltage and a concentration of an n-type dopant material;

FIG. 14 is a polygonal line graph illustrating a relationship between a driving voltage and a concentration of a p-type dopant material;

FIG. 15 is a schematic diagram illustrating a second exemplary structure of the organic light-emitting unit according to Embodiment 1;

FIG. 16 is a schematic diagram illustrating a third exemplary structure of the organic light-emitting unit according to Embodiment 1;

FIG. 17 illustrates bar graphs for comparison of the percentages of losses;

FIG. 18A illustrates exemplary comparative structures according to existing techniques;

FIG. 18B illustrates exemplary comparative structures according to embodiments of the present disclosure;

FIG. 19A illustrates an exemplary structure of a subpixel corresponding to a disclosed technical feature;

FIG. 19B illustrates an exemplary structure of a subpixel corresponding to an embodiment of the present disclosure;

FIG. 20 is a schematic diagram illustrating an exemplary structure of an organic light-emitting unit according to Embodiment 2;

FIG. 21 is a schematic diagram illustrating an exemplary structure of an organic light-emitting unit according to Embodiment 3;

FIG. 22 is a curve graph illustrating parameters including a reflection factor in the organic light-emitting unit;

FIG. 23 illustrates a bar graph for comparison of the percentages of losses;

FIG. 24 is a sectional view of the light-emitting units and driving TFTs;

FIG. 25 is a schematic diagram illustrating an exemplary structure of a display device according to Embodiment 4;

FIG. 26 is a plan view of a part of a display region of the display device;

FIG. 27 is a schematic diagram illustrating exemplary structures of in-vehicle displays according to Embodiment 5 and a vehicle including the in-vehicle displays;

FIG. 28 is a perspective view of an exemplary structure of a smartphone as an electronic device according to Embodiment 6;

FIG. 29A is a sectional view of a first sealing structure;

FIG. 29B is a sectional view of a second sealing structure;

FIG. 29C is a sectional view of a third sealing structure;

FIG. 30A is a schematic diagram illustrating an exemplary structure of an organic light-emitting unit in an existing technique;

FIG. 30B illustrates the emission intensities revealed by optical simulations in the existing technique;

FIG. 31 is a curve graph illustrating the emission intensities based on experiment results in the existing technique; and

FIG. 32 is a schematic diagram illustrating an exemplary tandem structure in another existing technique.

### DETAILED DESCRIPTION OF THE INVENTION

### Embodiment 1

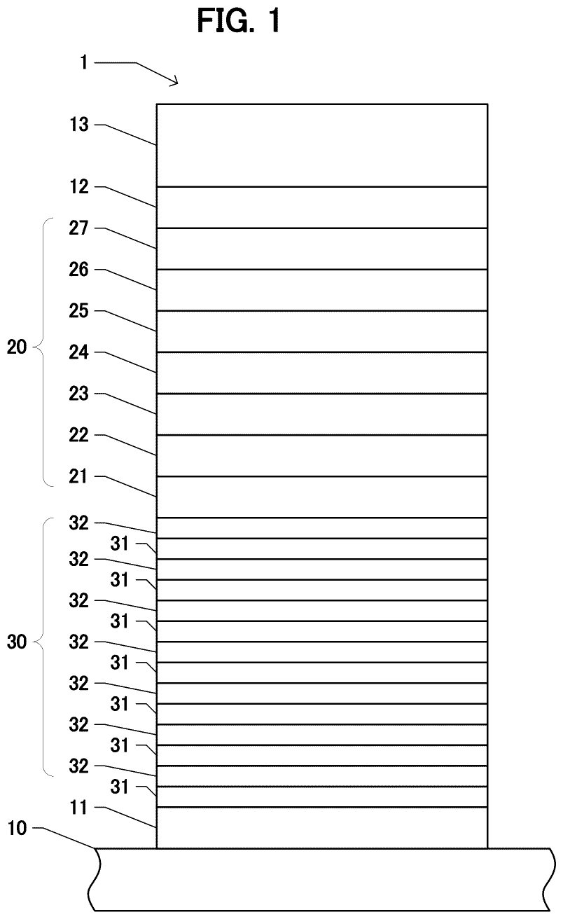

FIG. 1 is a schematic diagram illustrating a first exemplary structure of an organic light-emitting unit 1 according to an embodiment. The organic light-emitting unit 1 is a type of a top-emission OLED. The organic light-emitting unit 1 includes an anode electrode 11 and a cathode electrode 12 opposed to each other on a circuit board 10. The organic light-emitting unit 1 also includes a light-emitting mechanism 20 and an interference reflector 30 disposed between the anode electrode 11 and the cathode electrode 12. The organic light-emitting unit 1 further includes a capping layer 13 on the cathode electrode 12. The layered product made of organic compounds and held between the anode electrode 11 and the cathode electrode 12 are also called organic compound layers or organic material layers. The materials of the individual layers do not limit the scope of the present disclosure.

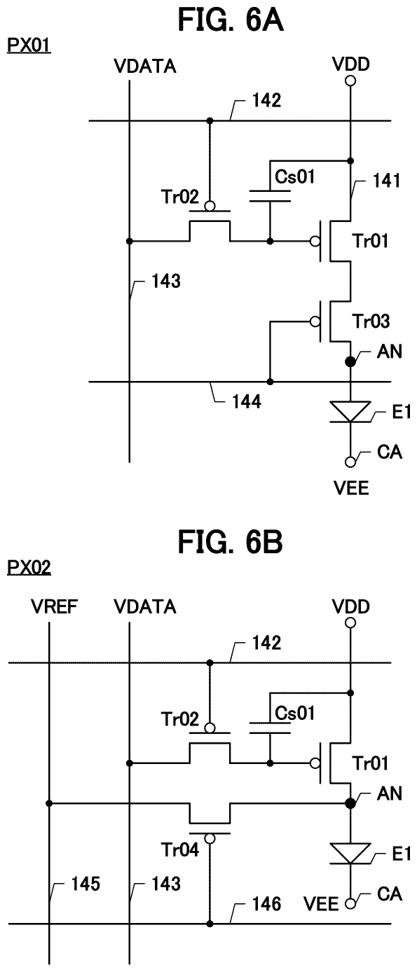

The circuit board 10 is an inflexible or flexible substrate provided with pixel circuits PX01 like that illustrated in FIG. 6A or pixel circuits PX02 like that illustrated in FIG. 6B, for example. The circuit board 10 includes a thin film transistor (TFT) array. The organic light-emitting unit 1 has a multilayer structure on the circuit board 10. The following describes FIG. 1 assuming that the circuit board 10 is adjacent to the bottom and distant from the top.

The anode electrode 11 is a lower electrode serving as a first electrode in the organic light-emitting unit 1. The anode electrode 11 is connected to a power source, which is not illustrated. The anode electrode 11 is any electrode made of a material having light permeability and conductivity. For example, the anode electrode 11 may be made of indium tin oxide (ITO), tin dioxide (SnO₂), or indium zinc oxide (IZO). The organic light-emitting unit 1 according to the embodiment does not require metallic reflection by the anode electrode 11. The anode electrode 11 may be an existing metal electrode provided that the interference reflector 30 has sufficient reflection properties.

The cathode electrode 12 is an upper electrode serving as a second electrode in the organic light-emitting unit 1. The cathode electrode 12 is connected to the power source, which is not illustrated. The cathode electrode 12 is any electrode made of a translucent and semi-reflective material. For example, the cathode electrode 12 may be made of aluminum, magnesium-silver alloy, ITO, or IZO.

The light-emitting mechanism 20 includes, in the order from the bottom, a hole injection layer 21, a hole transport layer 22, an electron blocking layer 23, a light-emitting layer 24, a hole blocking layer 25, an electron transport layer 26, and an electron injection layer 27. The light-emitting mechanism 20 may apply structures and materials of existing OLED elements or new structures and materials applicable to general OLED elements. The light-emitting mechanism 20 may exclude all or some of the hole injection layer 21, the hole transport layer 22, the electron blocking layer 23, the hole blocking layer 25, the electron transport layer 26, and the electron injection layer 27. In other words, the light-emitting mechanism 20 includes at least the light-emitting layer 24.

The hole injection layer 21 facilitates injection of holes by lowering the hole injection barrier from the anode electrode 11. In the hole injection layer 21, the energy level of the highest occupied molecular orbital (HOMO), referred to as the HOMO level, is lower than the work function of the anode electrode 11 but higher than the HOMO level of the hole transport layer 22. The hole injection layer 21 thus has a HOMO level between the work function of the anode electrode 11 and the HOMO level of the hole transport layer 22.

The hole transport layer 22 promotes the transport of holes to the light-emitting layer 24. In general, the hole transport layer 22 has a larger energy bandgap than the light-emitting layer 24. The energy bandgap means the difference in energy between the HOMO level and the energy level of the lowest unoccupied molecular orbital (LUMO), referred to as the LUMO level.

The electron blocking layer 23 inhibits movement of electrons. The electron blocking layer 23 prevents holes from accumulating at the interface between the hole transport layer 22 and the electron blocking layer 23 and the interface between the electron blocking layer 23 and the light-emitting layer 24.

The light-emitting layer 24 emits light due to the recombination of holes and electrons. The holes are injected from the anode electrode 11 to the light-emitting layer 24. The electrons are injected from the cathode electrode 12 to the light-emitting layer 24. The light-emitting layer 24 is any layer made of a fluorescent material, a thermally-activated delayed fluorescent material, a phosphorescent material, or any of other organic light-emitting materials.

The hole blocking layer 25 inhibits movement of holes. The hole blocking layer 25 prevents electrons from accumulating at the interface between the light-emitting layer 24 and the hole blocking layer 25 and the interface between the hole blocking layer 25 and the electron transport layer 26.

The electron transport layer 26 promotes the transport of electrons to the light-emitting layer 24. The electron transport layer 26 preferably has a larger energy bandgap than the light-emitting layer 24, like the hole transport layer 22. The electron transport layer 26 may inhibit movement of excitons generated in the light-emitting layer 24.

The electron injection layer 27 facilitates injection of electrons by lowering the electron injection barrier from the cathode electrode 12. In the electron injection layer 27, the LUMO level is higher than the work function of the cathode electrode 12 but lower than the LUMO level of the electron transport layer 26. That is, the electron injection layer 27 has a LUMO level between the work function of the cathode electrode 12 and the LUMO level of the electron transport layer 26.

As described above, the light-emitting mechanism 20 includes the hole injection layer 21, the hole transport layer 22, the electron injection layer 27, and the electron transport layer 26, between the anode electrode 11 and the cathode electrode 12. The interference reflector 30 is disposed between the anode electrode 11 and the cathode electrode 12, separately from the light-emitting mechanism 20. The interference reflector 30 is thus located at a position different from the hole injection layer 21, the hole transport layer 22, the electron injection layer 27, and the electron transport layer 26. The interference reflector 30 is disposed in contact with the hole injection layer 21 in the organic light-emitting unit 1 illustrated in FIG. 1.

The interference reflector 30 includes p-type low refractive-index layers 31 having a p-type of conductivity and a low refractive index, as first charge generating layers having a first type of conductivity and a first refractive index. The interference reflector 30 also includes n-type high refractive-index layers 32 having an n-type of conductivity and a high refractive index, as second charge generating layers having a second type of conductivity and a second refractive index. The p-type low refractive-index layers 31 and the n-type high refractive-index layers 32 are alternately stacked on each other in the interference reflector 30. The interference reflector 30 illustrated in FIG. 1 is disposed, between the anode electrode 11 and the light-emitting layer 24, in contact with the anode electrode 11. Materials having the p-type of conductivity have hole transport ability. Materials having the n-type of conductivity have electron transport ability.

The p-type low refractive-index layers 31 and the n-type high refractive-index layers 32 each have a refractive index and a film thickness defined in accordance with the emission wavelength. For example, the p-type low refractive-index layers 31 may have a refractive index equal to or higher than 1.4 and equal to or lower than 1.6. The n-type high refractive-index layers 32 may have a refractive index equal to or higher than 2.0 and equal to or lower than 2.2. The p-type low refractive-index layers 31 and the n-type high refractive-index layers 32 exhibit a refractive index difference of at least 0.4.

The p-type low refractive-index layers 31 may have a film thickness of approximately 120 nm, in the case of emitted light having a red visible light spectrum. The n-type high refractive-index layers 32 may have a film thickness of approximately 70 nm, in the case of emitted light having a red visible light spectrum. The p-type low refractive-index layers 31 may have a film thickness of approximately 90 nm, in the case of emitted light having a green visible light spectrum. The n-type high refractive-index layers 32 may have a film thickness of approximately 70 nm, in the case of emitted light having a green visible light spectrum. The p-type low refractive-index layers 31 may have a film thickness of approximately 65 nm, in the case of emitted light having a blue visible light spectrum. The n-type high refractive-index layers 32 may have a film thickness of approximately 55 nm, in the case of emitted light having a blue visible light spectrum.

The film thicknesses of the p-type low refractive-index layers 31 and the n-type high refractive-index layers 32 can be determined depending on the emission wavelength and refractive index. More specifically, the total film thickness of the p-type low refractive-index layers 31 and the n-type high refractive-index layers 32 may be determined to satisfy the condition of being one-fourth of the in-layer wavelength calculated by dividing the emission wavelength by the refractive index. The film thickness of each layer may have an error within 10% or less, for example. The p-type low refractive-index layers 31 and the n-type high refractive-index layers 32 in the interference reflector 30 each have a film thickness optimum for the wavelength of the color of emitted light.

The light emission spectrum of the light-emitting layer 24 demonstrates results of the microcavity effect generated between first and second reflection surfaces opposed to each other. The description defines the optical distance between the first and second reflection surfaces as L, and the peak wavelength of emitted light as A. The description also defines the observation angle of light emitted from the element as θ, measured relative to the 0° observation angle directly in front of the element. The description further defines the sum of phase shifts in reflection of emitted light at the first and second reflection surfaces as q [rad]. The optical distance L is equal to the total optical film thickness of the organic compound layers disposed between the first and second reflection surfaces. The optical film thickness is calculated by multiplying an actual film thickness by a refractive index. The sum φ of phase shifts varies depending on a combination of materials of the reflection interfaces when the emitted light is actually reflected at the first and second reflection surfaces. If these parameters have a relationship that satisfies Expression (1) below, the emitted light can be enhanced by the resonance effect.

$$\begin{matrix}[ Expression 1 ] & \\ 2 L cos θ + ϕ / 2 π = m λ ( m = 1 , 2 , 3 … ) & ( 1 )\end{matrix}$$

The cathode electrode 12 of the organic light-emitting unit 1 serves as the first reflection surface. The interference reflector 30 includes multiple second reflection surfaces defined by the interfaces between the p-type low refractive-index layers 31 and the n-type high refractive-index layers 32. The light emitted from the light-emitting layer 24 and the light reflected by the cathode electrode 12 are reflected at a predetermined reflection factor when propagating from one of the n-type high refractive-index layers 32 into one of the p-type low refractive-index layers 31. Varying the optical film thicknesses of the light-emitting mechanism 20 and the interference reflector 30 enables adjustment of the peak wavelength most enhanced by the resonance effect.

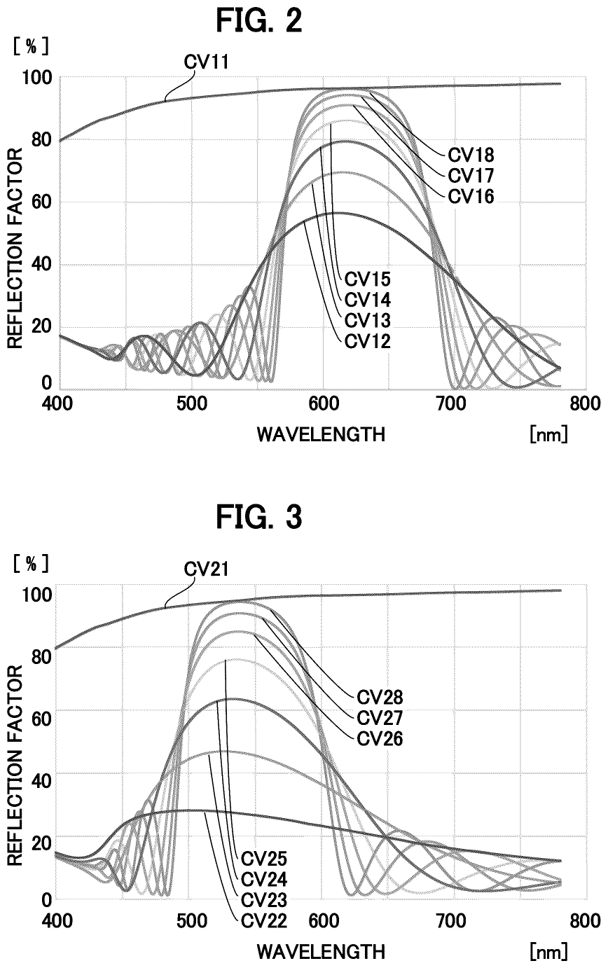

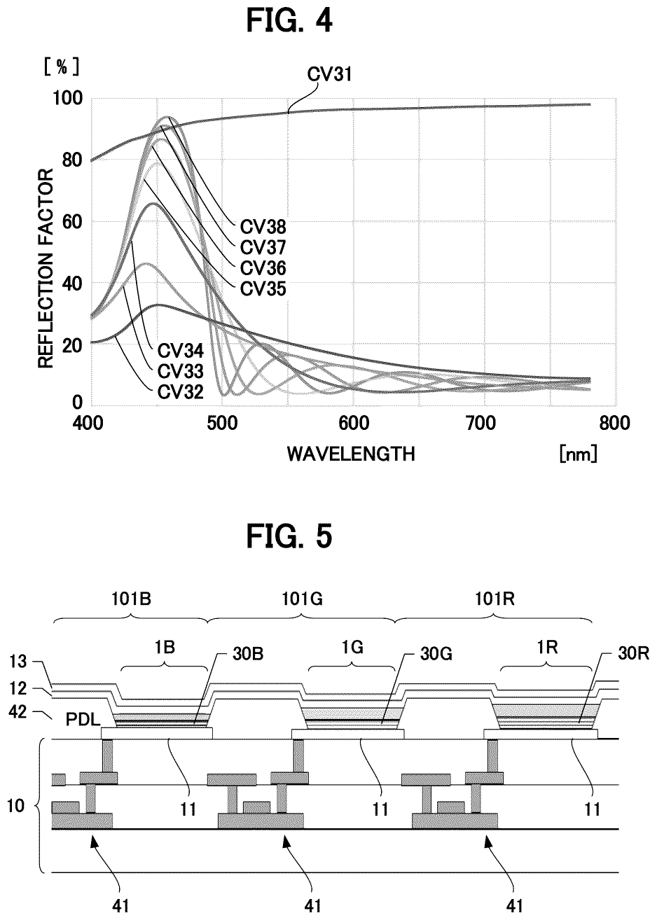

FIGS. 2 to 4 are each a curve graph illustrating exemplary simulations of reflection factors corresponding to different numbers of pairs of the p-type low refractive-index layers 31 and the n-type high refractive-index layers 32. FIG. 2 illustrates exemplary simulations corresponding to emitted light having a red visible light spectrum. FIG. 3 illustrates exemplary simulations corresponding to emitted light having a green visible light spectrum. FIG. 4 illustrates exemplary simulations corresponding to emitted light having a blue visible light spectrum.

In the exemplary simulations of red light illustrated in FIG. 2, the curve CV11 represents a reflection factor of an electrode having a three-layer structure of ITO/Ag/ITO made of ITO films retaining a thin silver film therebetween. The curve CV12 represents a reflection factor of a layered product including three pairs of the p-type low refractive-index layers 31 and the n-type high refractive-index layers 32. The curve CV13 represents a reflection factor of a layered product including four pairs of the p-type low refractive-index layers 31 and the n-type high refractive-index layers 32. The curve CV14 represents a reflection factor of a layered product including five pairs of the p-type low refractive-index layers 31 and the n-type high refractive-index layers 32. The curve CV15 represents a reflection factor of a layered product including six pairs of the p-type low refractive-index layers 31 and the n-type high refractive-index layers 32. The curve CV16 represents a reflection factor of a layered product including seven pairs of the p-type low refractive-index layers 31 and the n-type high refractive-index layers 32. The curve CV17 represents a reflection factor of a layered product including eight pairs of the p-type low refractive-index layers 31 and the n-type high refractive-index layers 32. The curve CV18 represents a reflection factor of a layered product including nine pairs of the p-type low refractive-index layers 31 and the n-type high refractive-index layers 32.

In the exemplary simulations of green light illustrated in FIG. 3, the curve CV21 represents a reflection factor of an electrode having a three-layer structure of ITO/Ag/ITO. The curve CV22 represents a reflection factor of a layered product including a single pair of the p-type low refractive-index layer 31 and the n-type high refractive-index layer 32. The curve CV23 represents a reflection factor of a layered product including two pairs of the p-type low refractive-index layers 31 and the n-type high refractive-index layers 32. The curve CV24 represents a reflection factor of a layered product including three pairs of the p-type low refractive-index layers 31 and the n-type high refractive-index layers 32. The curve CV25 represents a reflection factor of a layered product including four pairs of the p-type low refractive-index layers 31 and the n-type high refractive-index layers 32. The curve CV26 represents a reflection factor of a layered product including five pairs of the p-type low refractive-index layers 31 and the n-type high refractive-index layers 32. The curve CV27 represents a reflection factor of a layered product including six pairs of the p-type low refractive-index layers 31 and the n-type high refractive-index layers 32. The curve CV28 represents a reflection factor of a layered product including seven pairs of the p-type low refractive-index layers 31 and the n-type high refractive-index layers 32.

In the exemplary simulations of blue light illustrated in FIG. 4, the curve CV31 represents a reflection factor of an electrode having a three-layer structure of ITO/Ag/ITO. The curve CV32 represents a reflection factor of a layered product including a single pair of the p-type low refractive-index layer 31 and the n-type high refractive-index layer 32. The curve CV33 represents a reflection factor of a layered product including two pairs of the p-type low refractive-index layers 31 and the n-type high refractive-index layers 32. The curve CV34 represents a reflection factor of a layered product including three pairs of the p-type low refractive-index layers 31 and the n-type high refractive-index layers 32. The curve CV35 represents a reflection factor of a layered product including four pairs of the p-type low refractive-index layers 31 and the n-type high refractive-index layers 32. The curve CV36 represents a reflection factor of a layered product including five pairs of the p-type low refractive-index layers 31 and the n-type high refractive-index layers 32. The curve CV37 represents a reflection factor of a layered product including six pairs of the p-type low refractive-index layers 31 and the n-type high refractive-index layers 32. The curve CV38 represents a reflection factor of a layered product including seven pairs of the p-type low refractive-index layers 31 and the n-type high refractive-index layers 32.

These exemplary simulations reveal that the interference reflector 30 preferably includes at least seven pairs of the p-type low refractive-index layers 31 and the n-type high refractive-index layers 32 to achieve a reflection factor substantially equal to and at least 90% of the reflection factor of the electrode including a three-layer structure of ITO/Ag/ITO. The interference reflector 30 illustrated in FIG. 1 includes seven pairs of the p-type low refractive-index layers 31 and the n-type high refractive-index layers 32. In this interference reflector 30 of the organic light-emitting unit 1, seven p-type low refractive-index layers 31 having a p-type of conductivity and a low refractive index, corresponding to first charge generating layers having a first type of conductivity and a first refractive index, and seven n-type high refractive-index layers 32 having an n-type of conductivity and a high refractive index, corresponding to second charge generating layers having a second type of conductivity and a second refractive index, are alternately stacked on each other.

The p-type low refractive-index layers 31 having a p-type of conductivity as a first type of conductivity may be formed by using Lewis acid compounds which are electron-accepting compounds, such as molybdenum trioxide (MoO₃). The p-type low refractive-index layers 31 may also achieve the p-type of conductivity as the first type of conductivity, by adding any inorganic material functioning as an electron-accepting additive to an organic material functioning as a hole transport material through stacking or mixing with each other. The mixing may include doping. Examples of the inorganic material include vanadium pentoxide (V₂O₅), rhenium heptoxide (Re₂O₇), other metallic oxides, and metallic halides. Alternatively, the p-type of conductivity as the first type of conductivity may be achieved, by doping a host organic material functioning as a hole transport material with any organic dopant represented by a specific chemical formula and functioning as an electron-accepting additive. Examples of the organic dopant include organic materials having fluorine, cyano or other substituent groups as well as titanyl phthalocyanine, or other phthalocyanine compounds having a p-type of conductivity, and hexaazatriphenylene (HAT) derivatives such as hexaazatriphenylene hexacarbonitrile (HAT-CN). That is, the p-type low refractive-index layers 31 are each an organic material layer having electron acceptability and fabricated by doping a host transport material functioning as a charge transport material with impurities having the p-type of conductivity.

The n-type high refractive-index layers 32 having an n-type of conductivity as a second type of conductivity may be formed by using lithium fluoride (LiF) which is an electron-donating compound. The n-type high refractive-index layers 32 may also achieve the n-type of conductivity as the second type of conductivity, by adding any inorganic material functioning as an electron-donating additive to an organic material functioning as an electron transport material through stacking or mixing with each other. The mixing may include doping. Examples of the inorganic material include cesium fluoride (CsF), barium oxide (BaO), other alkali metals, alkaline earth metals, compounds thereof, and rare earth metals. Alternatively, the n-type of conductivity as the second type of conductivity may be achieved by doping a host organic material functioning as an electron transport material with any organic dopant represented by a specific chemical formula and functioning as an electron-donating additive. Examples of the organic dopant include antimony-phthalocyanine compounds and other phthalocyanine compounds having an n-type of conductivity. That is, the n-type high refractive-index layers 32 are each an organic material layers having-donating ability and fabricated by doping a host transport material functioning as a charge transport material with impurities having the n-type of conductivity.

The p-type low refractive-index layers 31 may achieve a low refractive index as a first refractive index, by introducing any of organic materials containing boron coordination compounds, such as condensed heterocyclic aromatic rings containing nitrogen and boron, organic materials having fluorine groups, and other inorganic and organic materials having low refractive indexes, for example. The n-type high refractive-index layers 32 may achieve a high refractive index as a second refractive index, by introducing any of aromatic amine derivatives, carbazole derivatives, benzimidazole derivatives, triazole derivatives, and other inorganic and organic materials having high refractive indexes, for example.

FIG. 5 is a sectional view of a red light-emitting unit 1R, a green light-emitting unit 1G, and a blue light-emitting unit 1B, or light-emitting subunits of three primary colors, and driving TFTs 41 for driving the individual light-emitting units. The organic light-emitting unit 1 according to the embodiment is applied to each of the red light-emitting unit 1R, the green light-emitting unit 1G, and the blue light-emitting unit 1B. The red light-emitting unit 1R includes an interference reflector 30R configured by adjusting the interference reflector 30 of the organic light-emitting unit 1 according to the embodiment for a red visible light spectrum. The green light-emitting unit 1G includes an interference reflector 30G configured by adjusting the interference reflector 30 of the organic light-emitting unit 1 according to the embodiment for a green visible light spectrum. The blue light-emitting unit 1B includes an interference reflector 30B configured by adjusting the interference reflector 30 of the organic light-emitting unit 1 according to the embodiment for a blue visible light spectrum.

FIG. 5 also illustrates a pixel defining layer (PDL) 42. The pixel defining layer 42 is a resin layer having a pattern of openings. Each of the openings of the pixel defining layer 42 exposes the anode electrode 11 included in the red light-emitting unit 1R, the green light-emitting unit 1G, or the blue light-emitting unit 1B. The pixel defining layer 42 mutually separates the light-emitting units adjacent to each other, including the red light-emitting units 1R, the green light-emitting units 1G, and the blue light-emitting units 1B.

The red light-emitting unit 1R, the driving TFT 41 provided in association therewith, a switching TFT fed with scan signals at the gate electrode, and a pixel circuit having a storage capacitor for retaining a pixel signal constitute a red light-emitting subpixel 101R that emits red light. The green light-emitting unit 1G, the driving TFT 41 provided in association therewith, a switching TFT, and a pixel circuit having a storage capacitor constitute a green light-emitting subpixel 101G that emits green light. The blue light-emitting unit 1B, the driving TFT 41 provided in association therewith, a switching TFT, and a pixel circuit having a storage capacitor constitute a blue light-emitting subpixel 101B that emits blue light. The driving TFT 41 is fabricated by a well-known technique, and is conductive to the anode electrode 11 of the associated light-emitting unit at a position below the pixel defining layer 42. Each of the red light-emitting unit 1R, the green light-emitting unit 1G, and the blue light-emitting unit 1B receives driving current from a power line via the driving TFT 41 provided in association with the light-emitting unit. The driving TFT 41 controls the driving current flowing in the red light-emitting unit 1R, the green light-emitting unit 1G, or the blue light-emitting unit 1B, in accordance with the voltage level of the pixel signal retained by the storage capacitor. The red light-emitting subpixel 101R, the green light-emitting subpixel 101G, and the blue light-emitting subpixel 101B are also called subpixels.

In the organic light-emitting unit 1 serving as the red light-emitting unit 1R, the light-emitting layer 24 exhibits a visible light spectrum of red as an exemplary first color. The interference reflector 30R illustrated in FIG. 5 is stacked on the anode electrode 11 included in the red light-emitting unit 1R. The p-type low refractive-index layers 31 and the n-type high refractive-index layers 32 in the interference reflector 30R each have a refractive index and a film thickness defined in accordance with the red visible light spectrum.

In the organic light-emitting unit 1 serving as the green light-emitting unit 1G, the light-emitting layer 24 exhibits a visible light spectrum of green as an exemplary second color. The interference reflector 30G illustrated in FIG. 5 is stacked on the anode electrode 11 included in the green light-emitting unit 1G. The p-type low refractive-index layers 31 and the n-type high refractive-index layers 32 in the interference reflector 30G each have a refractive index and a film thickness defined in accordance with the green visible light spectrum.

In the organic light-emitting unit 1 serving as the blue light-emitting unit 1B, the light-emitting layer 24 exhibits a visible light spectrum of blue as an exemplary third color. The interference reflector 30B illustrated in FIG. 5 is stacked on the anode electrode 11 included in the blue light-emitting unit 1B. The p-type low refractive-index layers 31 and the n-type high refractive-index layers 32 in the interference reflector 30B each have a refractive index and a film thickness defined in accordance with the blue visible light spectrum. The first to third colors may be any combination of colors having mutually different wavelengths.

As illustrated in FIG. 5, the circuit board 10, on which the anode electrode 11 and the cathode electrode 12 are opposed to each other, is compartmented into first, second, and third regions corresponding to the red light-emitting units 1R, the green light-emitting units 1G, and the blue light-emitting units 1B, respectively. Each of the first regions on the circuit board 10 is provided, between the anode electrode 11 and the cathode electrode 12, with the light-emitting layer 24 exhibiting a red visible light spectrum and included in the red light-emitting unit 1R, and provided with the interference reflector 30R for the red visible light spectrum on and in contact with the anode electrode 11. Each of the second regions on the circuit board 10 is provided, between the anode electrode 11 and the cathode electrode 12, with the light-emitting layer 24 exhibiting a green visible light spectrum and included in the green light-emitting unit 1G, and provided with the interference reflector 30G for the green visible light spectrum on and in contact with the anode electrode 11. Each of the third regions of the circuit board 10 is provided, between the anode electrode 11 and the cathode electrode 12, with the light-emitting layer 24 exhibiting a blue visible light spectrum and included in the blue light-emitting unit 1B, and provided with the interference reflector 30B for the blue visible light spectrum on and in contact with the anode electrode 11.

The organic light-emitting unit 1 includes the interference reflector 30 and does not require a reflective electrode made of metal films, thereby reducing the optical loss in the vicinity of the electrode caused by surface plasmon effect. The reduced optical loss leads to improved luminous efficiency. The resonant region in the microcavity structure has no electrode and thus avoids absorption of light by the electrode, also leading to improved luminous efficiency.

The circuit board 10 includes multiple pixel circuits. These pixel circuits control current fed to the individual anode electrodes 11 of multiple subpixels. FIG. 6A is a circuit diagram illustrating a pixel circuit PX01, as an exemplary first pixel circuit. FIG. 6B is a circuit diagram illustrating a pixel circuit PX02, as an exemplary second pixel circuit. The circuit board 10 includes, as the pixel circuits, multiple pixel circuits PX01 or multiple pixel circuits PX02.

The pixel circuit PX01 illustrated in FIG. 6A includes transistors Tr01 to Tr03 and a storage capacitor Cs01, and can control the light emission from a light-emitting element E1, such as the organic light-emitting unit 1 serving as the OLED element. An anode AN of the light-emitting element E1 corresponds to the anode electrode 11. A cathode CA of the light-emitting element E1 corresponds to the cathode electrode 12. The transistors Tr01 to Tr03 are all p-type TFTs. The transistor Tr01 is a driving TFT 41 provided in association with the light-emitting element E1. The transistor Tr02 is a TFT for controlling wiring of image signals as a switching TFT, and functions as a switch for selecting the subpixel. The transistor Tr03 is a TFT for controlling light emission as an emission transistor, and functions as a switch for controlling start and stop of feeding of driving current to the light-emitting element E1.

The gate terminal of the transistor Tr01 is connected to the drain terminal of the transistor Tr02. The source terminal of the transistor Tr01 is connected to a driving power line 141. The driving power line 141 is fed with driving voltage VDD. The drain terminal of the transistor Tr01 is connected to the source terminal of the transistor Tr03. The storage capacitor Cs01 is connected between the gate and source terminals of the transistor Tr01.

The gate terminal of the transistor Tr02 is connected to a scanning line 142. The source terminal of the transistor Tr02 is connected to a data line 143. The drain terminal of the transistor Tr02 is connected to the gate terminal of the transistor Tr01.

The gate terminal of the transistor Tr03 is connected to an emission control line 144. The source terminal of the transistor Tr03 is connected to the drain terminal of the transistor Tr01. The drain terminal of the transistor Tr03 is connected to the anode AN of the light-emitting element E1. The cathode CA of the light-emitting element E1 is fed with cathode voltage VEE.

The scanning line 142 transmits a selection pulse output from a component, such as a scan driver included in a display device. In response to the selection pulse, the transistor Tr02 switches from the off-state to the on-state. The data line 143 is fed with data voltage VDATA included in each of the image signals from a component, such as a driver IC included in the display device. The transistor Tr02 in the on-state causes the data voltage VDATA to be stored as the pixel signal into the storage capacitor Cs01. The storage capacitor Cs01 retains the stored voltage for one frame period. The voltage retained by the storage capacitor Cs01 varies the conductance of the transistor Tr01 in analog form. The transistor Tr01 thus feeds the light-emitting element E1 with forward bias current corresponding to light emission gradations.

The transistor Tr03 is located on the route of feeding the driving current. The emission control line 144 transmits a control signal output from a component, such as an emission driver of the display device. The control signal in the emission control line 144 is used to control the activation or deactivation of the transistor Tr03. The transistor Tr03 in the on-state causes the driving current to be fed to the light-emitting element E1. The transistor Tr03 in the off-state stops the feeding of the driving current. This control of the activation and deactivation of the transistor Tr03 can adjust a duty ratio, which indicates a lighting period within one field period.

The pixel circuit PX02 illustrated in FIG. 6B includes a transistor Tr04, instead of the transistor Tr03 of the pixel circuit PX01. The transistor Tr04 controls the electrical connection between a reference voltage supply line 145 and the anode AN of the light-emitting element E1. The reference voltage supply line 145 is fed with reference voltage VREF. The gate terminal of the transistor Tr04 is connected to a reset control line 146. The reset control line 146 transmits a reset control signal output from a component, such as a reset IC of the display device. The reset control signal in the reset control line 146 is used to control the activation or deactivation of the transistor Tr04.

The transistor Tr04 may also be used to reduce the cross talk caused by leak current between the light-emitting elements E1. For example, the transistor Tr04 may reset the anode AN of the light-emitting element E1 to have a sufficiently low voltage equal to or lower than the black signal level.

The transistor Tr04 may also be used to measure the characteristics of the transistor Tr01 functioning as a driving transistor. For example, a bias condition is selected in which the transistor Tr01 operates in the saturation region and the transistor Tr04 operates in the linear region. Under this bias condition, the characteristics of voltage-to-current conversion of the transistor Tr01 can be accurately determined by measuring the current flowing from the driving power line 141 having the driving voltage VDD to the reference voltage supply line 145 having the reference voltage VREF. The differences in characteristics of voltage-to-current conversion among the transistors Tr01 included in different subpixels can be compensated for by data signals generated by an external circuit. This compensation allows the display device to generate a display image having high uniformity.

The transistor Tr04 may also be used to accurately measure the voltage-current characteristics of the light-emitting element E1. For example, the transistor Tr04 operates in the linear region when the transistor Tr01 is in the off-state. In this situation, the voltage for light emission from the light-emitting element E1 is fed from the reference voltage supply line 145. For example, the deterioration of the light-emitting element E1 after long time use can be compensated for by a data signal generated by an external circuit. This compensation can extend the life-span of the display device.

The circuit board 10 may also be provided with pixel circuits having a circuit configuration different from the pixel circuit PX01 illustrated in FIG. 6A and the pixel circuit PX02 illustrated in FIG. 6B. The transistors Tr01 to Tr04 may be n-type TFTs, instead of the p-type TFTs. The pixel circuits PX01, the pixel circuits PX02, and other pixel circuits are only required to compensate for variations in threshold voltage of the transistors Tr01 functioning as driving transistors, and thus avoid degradation in image quality. Display irregularities that are insufficiently suppressed by the pixel circuits may be mitigated through any technique designed to reduce the differences in characteristics of the transistors.

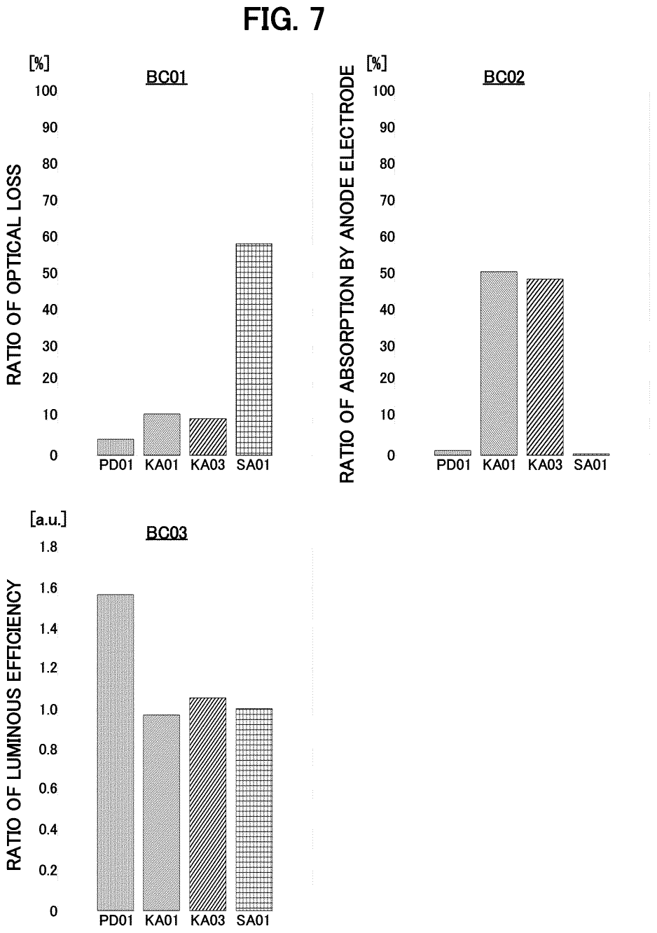

FIG. 7 illustrates bar graphs BC01 to BC03 for comparison of optical losses and luminous efficiencies revealed by optical simulations. The bar graph BC01 represents ratios of optical loss caused by the surface plasmon effect. The bar graph BC02 represents ratios of absorption by the anode electrodes, such as ITO layers. The bar graph BC03 represents ratios of luminous efficiency compared to those of existing structures. The x axis presents a structure PD01 according to the embodiment of the present disclosure accompanied by comparative examples including a technical feature KA01, a technical feature KA03, and an existing structure SA01. The technical feature KA01 indicates a structure like that disclosed in Unexamined Japanese Patent Application Publication No. 2007-317591. Specifically, the structure includes an ITO layer as the anode electrode, a dielectric mirror fabricated by stacking high refractive-index dielectric layers and low refractive-index dielectric layers on each other below the ITO layer, and a light reflecting layer below the dielectric mirror. The technical feature KA03 indicates a structure like that disclosed in U.S. Patent Application Publication No. 2015/0041768. Specifically, the structure includes an ITO layer as the anode electrode, and a reflection mechanism fabricated by stacking high refractive-index copolymer layers and low refractive-index copolymer layers on each other at the lower portion on the rear side of a TFT substrate. The existing structure SA01 includes a reflective metal electrode as the anode electrode. The bar graphs BC01 to BC03 demonstrate the results all provided by optical simulations in the present disclosure.

The ratios of optical loss represented by the bar graph BC01 can be obtained as the optical loss caused by the surface plasmon effect through calculation of Purcell factors. The existing structure SA01 exhibits a ratio of optical loss of almost 60%. In contrast, the technical features KA01 and KA03, including the ITO layers as the anode electrodes, exhibit reduced ratios of optical loss of approximately 10%. The structure PD01 according to the embodiment of the present disclosure, including the interference reflector 30 above the anode electrode 11, exhibits a further reduced ratio of optical loss of approximately 5%.

The bar graph BC02 represents ratios of absorption by the anode electrodes formed in the microcavity structures. The technical feature KA01 includes the dielectric mirror below the anode electrode made of ITO as the first electrode. The dielectric mirror of the technical feature KA01 serves as an optical resonator. The technical feature KA03 includes the TFT array substrate and an optical member below the anode electrode made of ITO as the first electrode. The optical members of the technical feature KA03 selectively reflect the light having wavelengths corresponding to the luminescent color of the light-emitting layer. These structures each cause the light emitted from the light-emitting layer and the light reflected by the reflection mechanism to pass through the anode electrode made of ITO repeatedly. The technical features KA01 and KA03 thus require a relatively large film thickness of the ITO layer, in order to achieve the sheet resistance comparable to that of the existing three-layer structure SA01 of ITO/Ag/ITO, for example. Such a relatively thick ITO layer absorbs a greater amount of light. The structure PD01 according to the embodiment of the present disclosure, including the interference reflector 30 above the anode electrode 11, exhibits a ratio of absorption of substantially 0%, like the existing structure SA01.

The bar graph BC03 represents ratios of luminous efficiency. The technical features KA01 and KA03 exhibit substantially the same luminous efficiencies as that of the existing structure SA01. In contrast, the structure PD01 according to the embodiment of the present disclosure, including the interference reflector 30 above the anode electrode 11, can achieve a luminous efficiency more than 1.5 times greater than that of the existing structure SA01. As described above, the structure PD01 according to the embodiment of the present disclosure including the interference reflector 30 does not require a reflective electrode made of a metal electrode and prevents light from being absorbed by the anode electrode made of ITO, thereby achieving improved luminous efficiency.

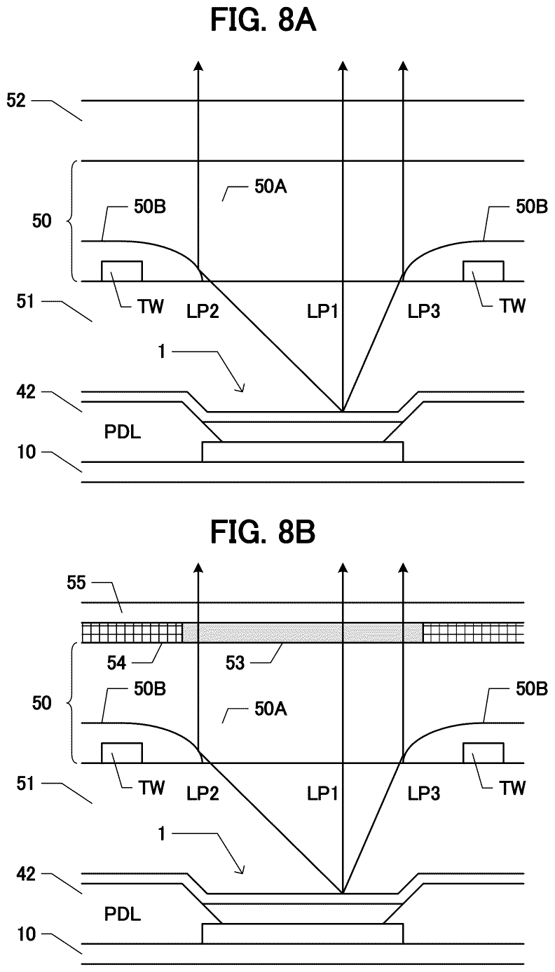

The light emitted from an organic light-emitting element having a component parallel to the light-emitting surface is partially reflected, and cannot be fully extracted to the outside. Enhancing the efficiency of such extraction of light can possibly further improve the luminous efficiency of the organic light-emitting element. To enhance the light extraction efficiency, the organic light-emitting unit 1 may have a microlens structure as an external or internal structure. FIGS. 8A and 8B are each a schematic diagram illustrating an exemplary structure of a light extraction layer 50 applicable as an external structure of the organic light-emitting unit 1. The organic light-emitting unit 1 is provided with a sealing layer 51 thereon. For example, the sealing layer 51 is made of hard glass, or a transparent inorganic or organic material having flexibility. The light extraction layer 50 is stacked on the sealing layer 51. The light extraction layer 50 illustrated in FIG. 8A is provided with a polarizing plate 52 thereon. The light extraction layer 50 illustrated in FIG. 8B is provided with a color filter 53, a black matrix 54, and an antireflection layer 55 thereon. The light extraction layer 50 illustrated in FIG. 8A or 8B is located in a plane different from the circuit board 10, on the outer side of the anode electrode 11 and the cathode electrode 12 opposed to each other on the circuit board 10.

The light extraction layer 50 includes a high refractive-index portion 50A and low refractive-index portions 50B. The high refractive-index portion 50A overlaps with the light-emitting layer 24 of the organic light-emitting unit 1 or other components, in the direction perpendicular to the plane of the circuit board 10, the light-emitting layer 24, or another layer. The high refractive-index portion 50A adjoins the tops of the low refractive-index portions 50B. In contrast, each of the low refractive-index portions 50B does not overlap with the light-emitting layer 24 of the organic light-emitting unit 1 or other components, but overlaps with the pixel defining layer 42 in the direction perpendicular to the plane of the circuit board 10, the light-emitting layer 24, or another layer. The low refractive-index portion 50B surrounds the light-emitting layer 24 of the organic light-emitting unit 1 or other components. The low refractive-index portion 50B has a thickness gradually decreasing, in the direction from the side of the pixel defining layer 42 farther from the light-emitting layer 24 of the organic light-emitting unit 1 or other components to the side closer to the light-emitting layer 24 of the organic light-emitting unit 1 or other components in parallel to the plane of the circuit board 10, the light-emitting layer 24, or another layer, and thus defines a curved edge. In other words, the thickness of the low refractive-index portion 50B increases in a curved shape, in the direction from the closer side to the further side of the light-emitting layer 24 of the organic light-emitting unit 1 or other components in parallel to the plane of the circuit board 10, the light-emitting layer 24, or another layer.

The light extraction layer 50 illustrated in FIG. 8A or 8B causes the light vertically emitted from the organic light-emitting unit 1 to linearly propagate in the high refractive-index portion 50A as indicated by the arrow LP1 and then be extracted to the outside. In contrast, the light diagonally emitted from the organic light-emitting unit 1 is refracted at the light extraction layer 50, as indicated by the arrow LP2 or LP3. According to the principle of light refraction, light at an incident angle higher than the critical angle is totally reflected when entering from a medium having a high refractive index into a medium having a low refractive index. As indicated by the arrow LP2 or LP3, the light from the organic light-emitting unit 1 is deflected in the vertical direction because the light is totally reflected at the interfaces between the high refractive-index portion 50A and the low refractive-index portion 50B. This structure increases the probability of emission of the light from the organic light-emitting unit 1 to the outside, thereby achieving improved light extraction efficiency.

The display device including the organic light-emitting unit may have a touch panel function. In this modification, the light extraction layer 50 illustrated in FIG. 8A or 8B may be mounted on a wiring TW of the touch panel.

The polarizing plate 52 illustrated in FIG. 8A serves as an antireflection film to avoid visibility impairment due to reflection of external light. The polarizing plate 52, however, blocks not only external light but also a part of the light emitted from the organic light-emitting unit 1, and thus hinders the improvement of the luminous efficiency. The polarizing plate 52 has a certain thickness and thus hinders the thickness reduction and the flexibility improvement. In contrast, the color filter 53, the black matrix 54, and the antireflection layer 55 illustrated in FIG. 8B improves the luminous efficiency while reducing the reflection of external light, thereby facilitating the thickness reduction and the flexibility improvement. For example, the color filter 53 can block the external light having wavelengths other than a certain wavelength and thus enhance the monochromaticity of the organic light-emitting unit 1. The black matrix 54 can absorb external light and reflected light. The color filter 53, the black matrix 54, and the antireflection layer 55 illustrated in FIG. 8B can thus eliminate the need for the polarizing plate 52 illustrated in FIG. 8A or a circularly polarizing plate serving as a retardation film.

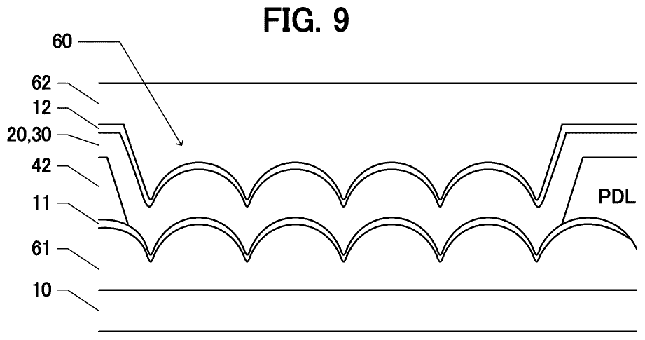

FIG. 9 is a schematic diagram illustrating a microlens array 60 applicable as an internal structure of the organic light-emitting unit 1. The circuit board 10 illustrated in FIG. 9 is provided with a smoothing layer 61 thereon. The top of the smoothing layer 61 is provided with the organic light-emitting unit 1 including the anode electrode 11 and the cathode electrode 12 opposed to each other, the light-emitting mechanism 20, and the interference reflector 30, formed as the microlens array 60. The microlens array 60 is provided with an overcoat layer 62 thereon. The top of the overcoat layer 62 may be provided with all or some of a wavelength converting layer, a passivation layer, a face film, and a protection film.

Below the overcoat layer 62, the anode electrode 11, the cathode electrode 12, the light-emitting mechanism 20, and the interference reflector 30 are arranged along the shapes of the locally maximum portions, inclined portions, and locally minimum portions of the surface of the overcoat layer 62, and shaped as a microlens array. The locally minimum portions are made of the portions of the microlens array 60 encompassing two or more microlenses adjacent to each other. The locally maximum portions are made of the central portions of the microlenses. The inclined portions are made of the portions between the locally maximum portions and the locally minimum portions. The components of the organic light-emitting unit 1, such as the anode electrode 11, the cathode electrode 12, the light-emitting mechanism 20, and the interference reflector 30 in the microlens array 60 have the same shapes as the locally maximum portions, the locally minimum portions, and the inclined portions of the microlenses in the overcoat layer 62.

The light generated by the light-emitting mechanism 20 is repetitively reflected between the cathode electrode 12 and the interference reflector 30. The propagating direction of the light is changed by the shape of the microlenses into the direction perpendicular to the plane of the circuit board 10. The microlens array 60 is disposed across the entire light-emitting region of the organic light-emitting unit 1. This structure increases the probability of emission of the light from the organic light-emitting unit 1 to the outside, thereby achieving improved light extraction efficiency.

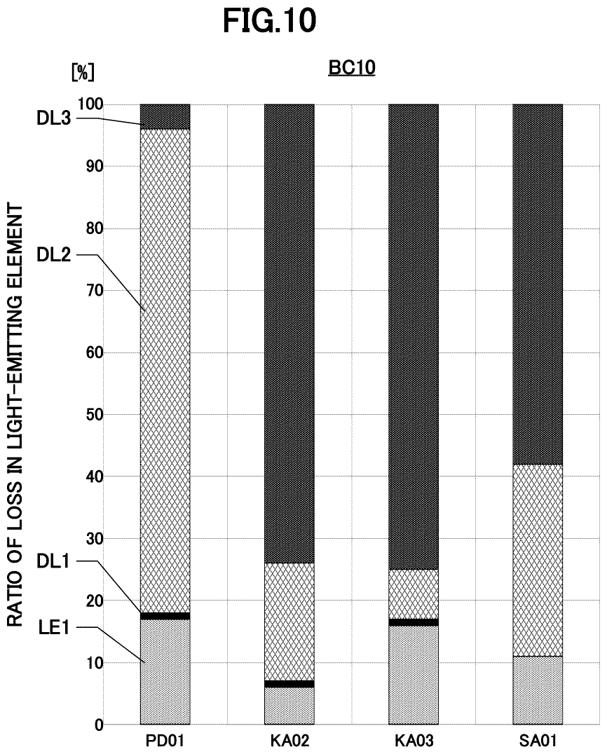

FIG. 10 illustrates a bar graph BC10 for comparison of the percentages of losses in light-emitting elements revealed by optical simulations. The x axis of the bar graph BC10 presents the structure PD01 according to the embodiment of the present disclosure accompanied by comparative examples including technical features KA02 and KA03 and the existing structure SA01. The technical feature KA02 includes, like the technique disclosed in Unexamined Japanese Patent Application Publication No. 2023-4940, organic layers each having a high or low refractive index and a n- or p-type of conductivity, between a light-emitting layer and an anode electrode. The technical feature KA03 includes, like the technique disclosed in U.S. Patent Application Publication No. 2015/0041768, an anode electrode made of ITO, and a reflection mechanism fabricated by stacking high refractive-index copolymer layers and low refractive-index copolymer layers at the lower portion on the rear side of a TFT substrate. The existing technique SA01 includes a reflective metal electrode as the anode electrode. The bar graph BC10 demonstrates the results provided by optical simulations in the present disclosure. The light emitted from a light-emitting element consists of an emitted light LE1, a loss DL1 caused by absorption by materials, a loss DL2 caused by optical confinement in organic layers, and an optical loss DL3.

The existing structure SA01 exhibits a ratio of the optical loss DL3 of almost 60%. The technical features KA02 and KA03 exhibit ratios of the optical loss DL3 higher than 70%. Such large optical losses may inhibit these structures from efficiently extracting light regardless of any light extraction technique. The technical features KA02 and KA03 enhance the microcavity effect and the monochromaticity, but suffer from large optical losses.

In contrast, the structure PD01 according to the embodiment of the present disclosure, including the interference reflector 30, exhibits a ratio of the optical loss DL3 of approximately 5%. The structure PD01 according to the embodiment of the present disclosure has the loss DL2 caused by optical confinement in organic layers that accounts for the majority of the total loss. The structure PD01 according to the embodiment of the present disclosure can thus efficiently extract emitted light by means of a light extraction technique, thereby achieving significantly improved luminous efficiency.

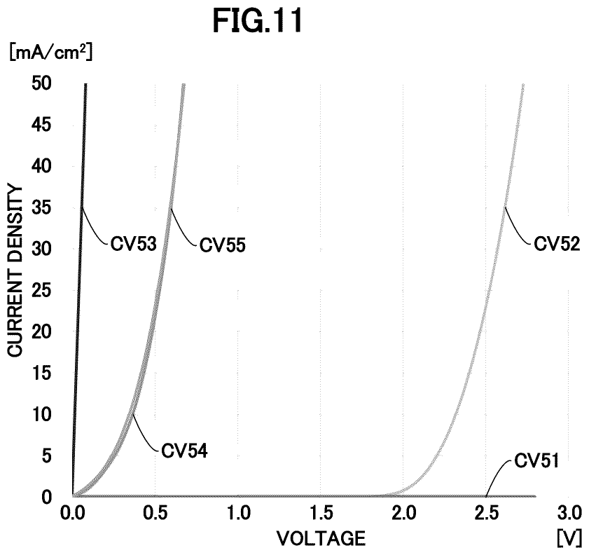

FIG. 11 illustrates a curve graph for comparison of the current-voltage characteristics of the organic material layers disposed between the anode electrode 11 and the cathode electrode 12. This comparison is based on test elements made of the materials of the hole transport layer 22, the electron transport layer 26, the p-type low refractive-index layers 31, and the n-type high refractive-index layers 32 of the organic light-emitting unit 1. The test elements made of these materials are connected to test electrodes made of the same materials as those of the anode electrode 11 and the cathode electrode 12. A first test element is a single layer element made of the materials of the electron transport layer 26 and having a film thickness of 20 nm. A second test element is a single layer element made of the materials of the hole transport layer 22 and having a film thickness of 20 nm. A third test element is a single layer element made of the materials of the n-type high refractive-index layers 32 and having a film thickness of 20 nm. A fourth test element is a single layer element made of the materials of the p-type low refractive-index layers 31 and having a film thickness of 20 nm. A fifth test element is a multilayer element that has a film thickness of 40 nm, and includes a layer made of the materials of the p-type low refractive-index layers 31 and having a film thickness of 20 nm, and a layer made of the materials of the n-type high refractive-index layers 32 and having a film thickness of 20 nm.

The curve CV51 in the curve graph illustrated in FIG. 11 represents the characteristics of the first test element. The curve CV52 represents the characteristics of the second test element. The curve CV53 represents the characteristics of the third test element. The curve CV54 represents the characteristics of the fourth test element. The curve CV55 represents the characteristics of the fifth test element. The p-type low refractive-index layers 31 and the n-type high refractive-index layers 32 have higher conductivity than the hole transport layer 22 and the electron transport layer 26. The fifth test element, fabricated by stacking a p-type low refractive-index layer 31 and an n-type high refractive-index layer 32 on each other, has substantially the same conductivity as the fourth test element made of a p-type low refractive-index layer 31. The interference reflector 30 of the organic light-emitting unit 1, has the multilayer structure including the p-type low refractive-index layers 31 and the n-type high refractive-index layers 32 having high electrical conductivity, and can thus suppress a voltage increase compared to the charge transport layers, such as the hole transport layer 22 and the electron transport layer 26. That is, the organic light-emitting unit 1, including the interference reflector 30 fabricated by stacking the p-type low refractive-index layers 31 and the n-type high refractive-index layers 32 on each other, enables both a lower driving voltage and a lower power consumption.

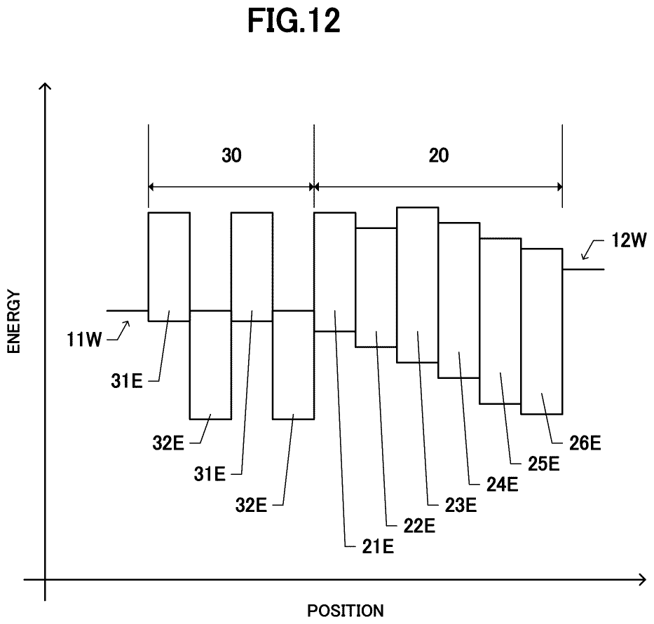

FIG. 12 illustrates energy states of the individual layers of the organic light-emitting unit 1. The energy states illustrated in FIG. 12 include a work function 11W of the anode electrode 11 and a work function 12W of the cathode electrode 12. The energy states of the individual layers of the light-emitting mechanism 20 include an energy state 21E of the hole injection layer 21, an energy state 22E of the hole transport layer 22, an energy state 23E of the electron blocking layer 23, an energy state 24E of the light-emitting layer 24, an energy state 25E of the hole blocking layer 25, and an energy state 26E of the electron transport layer 26 and the electron injection layer 27. The energy states of the individual layers of the interference reflector 30 include energy states 31E of the p-type low refractive-index layers 31 and energy states 32E of the n-type high refractive-index layers 32. The organic light-emitting unit 1 in the example illustrated in FIG. 12 includes two pairs of the p-type low refractive-index layers 31 and the n-type high refractive-index layers 32. The energy states may further include additional energy states 31E of the p-type low refractive-index layers 31 and additional energy states 32E of the n-type high refractive-index layers 32 depending on the number of pairs. The upper limit of the energy state of each layer represents the LUMO level indicating the orbital having the lowest energy in the conduction band, and the lower limit represents the HOMO level indicating the orbital having the highest energy in the valence band.

When voltage is applied across the anode electrode 11 and the cathode electrode 12, the cathode electrode 12 feeds electrons via the electron injection layer 27 and the electron transport layer 26 of the light-emitting mechanism 20 to the LUMO level of the light-emitting layer 24, whereas the anode electrode 11 feeds holes via the hole injection layer 21 and the hole transport layer 22 of the light-emitting mechanism 20 to the HOMO level of the light-emitting layer 24. The electrons and holes fed to the light-emitting layer 24 recombine with each other inside the light-emitting layer 24 and generate light.

The interference reflector 30 of the organic light-emitting unit 1 has the multilayer structure including the p-type low refractive-index layers 31 and the n-type high refractive-index layers 32 having mutually different polarities. This multilayer structure provides charge transfer complexes formed between the p-type low refractive-index layers 31 having electron acceptability and the n-type high refractive-index layers 32 having electron-donating ability, and is capable of transporting electric charges without hindering the feeding of carriers to the individual layers. That is, the multilayer structure can be fabricated as a low-voltage pn junction multi-unit. In FIG. 12, charge transfer complexes are generated due to redox reactions at the interfaces between the p-type low refractive-index layers 31 and the n-type high refractive-index layers 32. Applied voltage causes the holes in the charge transfer complexes to move toward the hole transport layer 22 and causes the electrons to move toward the anode electrode 11. This structure can prevent the interference reflector 30 from raising the voltage between the anode electrode 11 and the cathode electrode 12, and allows carriers to be smoothly injected from the side of the anode electrode 11 via the interference reflector 30 into the hole injection layer 21.

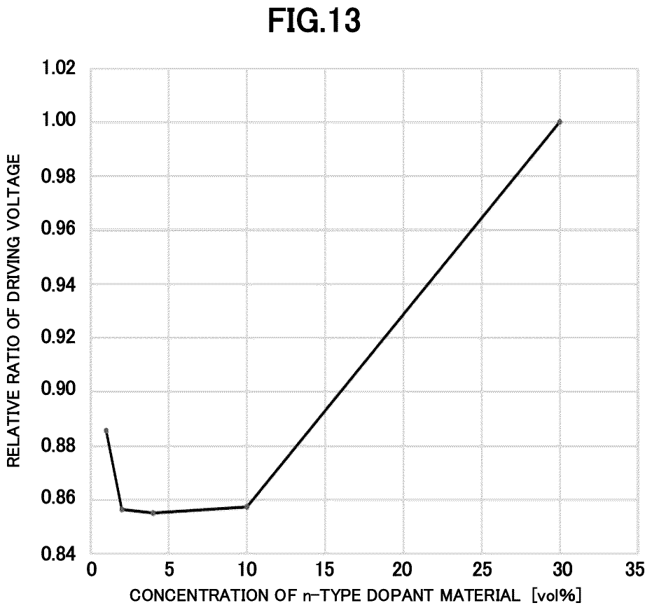

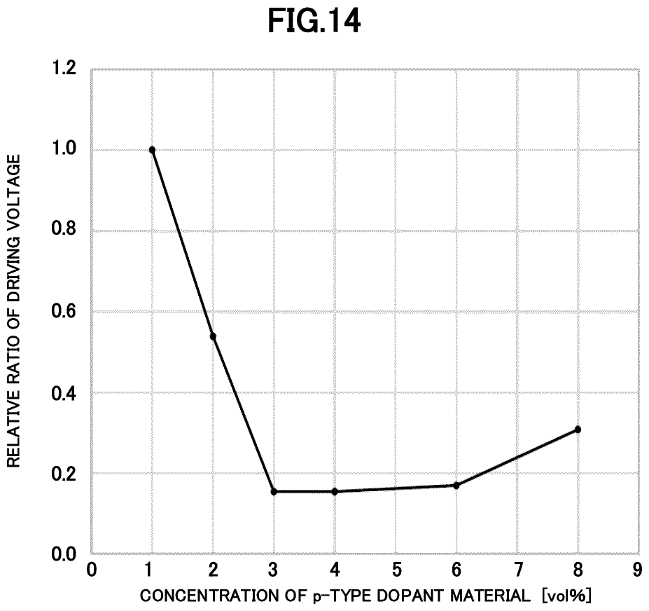

The electrical properties of the p-type low refractive-index layers 31 vary depending on the concentration of the p-type dopant, whereas the electrical properties of the n-type high refractive-index layers 32 vary depending on the concentration of the n-type dopant. FIG. 13 illustrates a relationship between the driving voltage of the light-emitting element according to the present disclosure and the concentration of the n-type dopant material in the n-type high refractive-index layers 32 (that is, the concentration of the n-type dopant in the n-type high refractive-index layers). This example assumes the concentration of the p-type dopant material in the p-type low refractive-index layers 31 set at 3%. FIG. 14 illustrates a relationship between the relative ratio of the driving voltage and the concentration of the p-type dopant material in the p-type low refractive-index layers 31 (that is, the concentration of the p-type dopant in the p-type low refractive-index layers) when the driving voltage of the light-emitting element according to the present disclosure is standardized by the driving voltage at a concentration of the p-type dopant material of 1% in the p-type low refractive-index layers 31. This example assumes the concentration of the n-type dopant material in the n-type high refractive-index layers 32 set at 4%.

The results illustrated in FIGS. 13 and 14 demonstrate that effective feeding of carries from the multilayer structure including the p-type low refractive-index layers 31 and the n-type high refractive-index layers 32 is facilitated by a certain concentration of the n-type dopant in the n-type high refractive-index layers and a certain concentration of the p-type dopant in the p-type low refractive-index layer. More specifically, the formation of the above-mentioned charge transfer complexes prefers a concentration of the n-type dopant in the n-type high refractive-index layers within the range of 2% to 10% and a concentration of the p-type dopant in the p-type low refractive-index layers within the range of 3% to 6%.

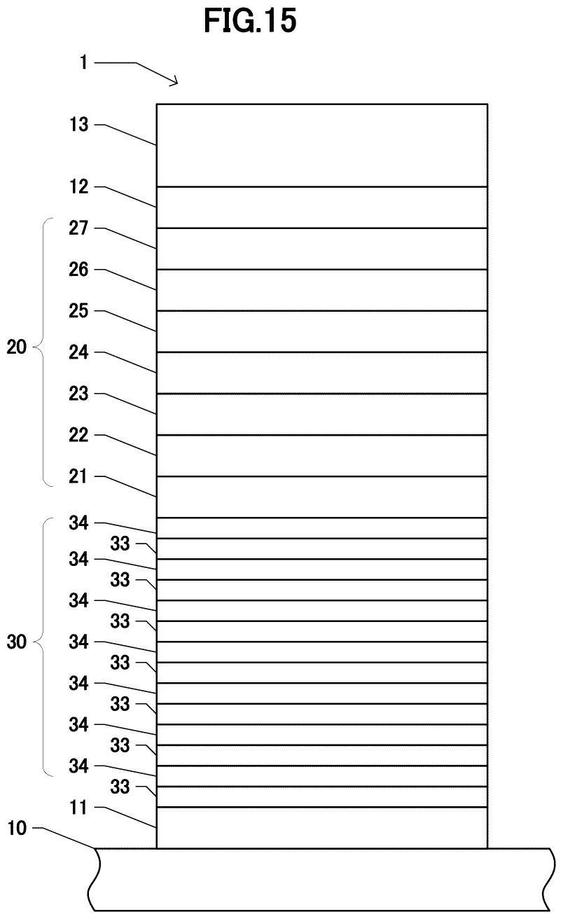

The light-emitting mechanism 20 stacked on the interference reflector 30 can apply an existing element structure and is thus less susceptible to changes in carrier balance, thereby preventing a decrease in luminous efficiency and a reduction in lifespan. The carrier balance, corresponding to the probability of generating excited states resulting from recombination of electrons and holes injected from the electrodes, contributes to the external quantum efficiency. FIG. 15 is a schematic diagram illustrating a second exemplary structure of the organic light-emitting unit 1 according to the embodiment. In FIG. 15, the component identical to that in FIG. 1 is provided with the same reference symbol. The interference reflector 30 of the organic light-emitting unit 1 illustrated in FIG. 15 includes n-type low refractive-index layers 33 having an n-type of conductivity and a low refractive index, as the first charge generating layers having a first type of conductivity and a first refractive index. The interference reflector 30 of the organic light-emitting unit 1 illustrated in FIG. 15 also includes p-type high refractive-index layers 34 having a p-type of conductivity and a high refractive index, as the second charge generating layers having a second type of conductivity and a second refractive index. In the interference reflector 30 illustrated in FIG. 15, the n-type low refractive-index layers 33 and the p-type high refractive-index layers 34 are alternately stacked on each other. The interference reflector 30 illustrated in FIG. 15 is disposed, between the anode electrode 11 and the light-emitting layer 24, in contact with the anode electrode 11. That is, the layers of the interference reflector 30 may have any combination of the p- or n-type of conductivity and the low or high refractive index, as the first or a second type of conductivity and the first or second refractive index.

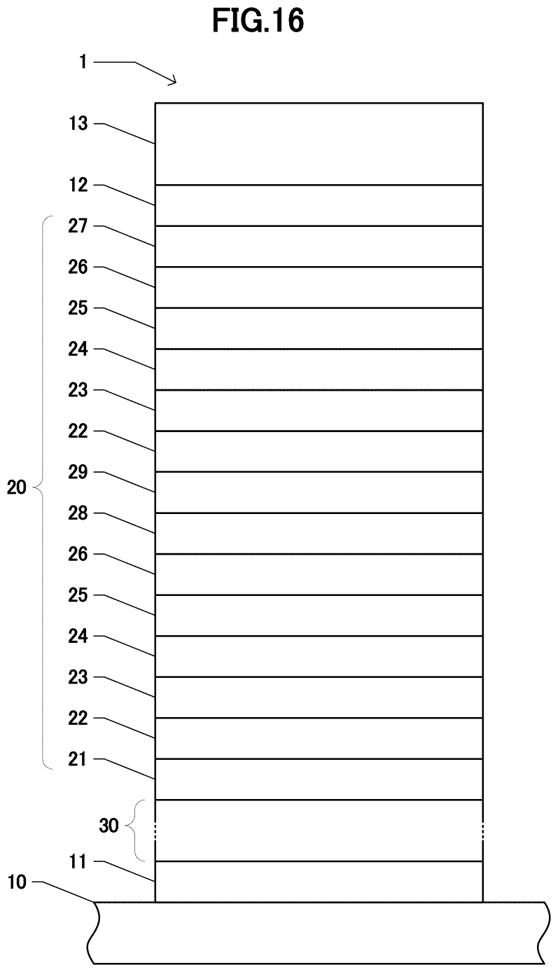

FIG. 16 is a schematic diagram illustrating a third exemplary structure of the organic light-emitting unit 1 according to the embodiment. In FIG. 16, the component identical to that in FIG. 1 is provided with the same reference symbol. The light-emitting mechanism 20 of the organic light-emitting unit 1 illustrated in FIG. 16 has a tandem structure including two layer groups each including the hole transport layer 22 to the electron transport layer 26, between the hole injection layer 21 and the electron injection layer 27. The tandem structure further includes, between the first layer group including the hole transport layer 22 to the electron transport layer 26 and the second layer group including the hole transport layer 22 to the electron transport layer 26, an n-type charge generating layer 28 and a p-type charge generating layer 29. The interference reflector 30 illustrated in FIG. 16 is disposed, between the anode electrode 11 and the lower light-emitting layer 24, in contact with the anode electrode 11.

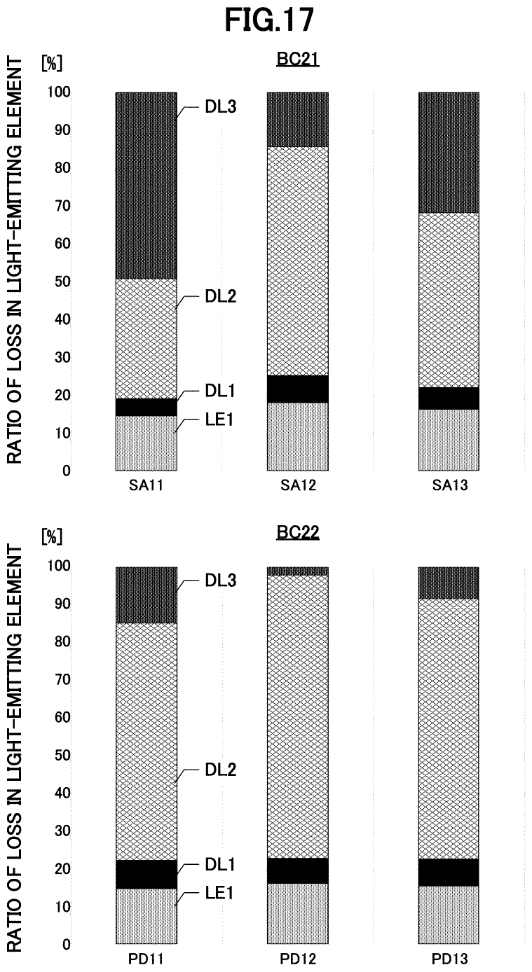

FIG. 17 illustrates bar graphs BC21 and BC22 for comparison of the percentages of losses between an existing structure and the embodiment of the present disclosure. The x axis of the bar graph BC21 presents comparative examples including a first single structure SA11, a second single structure SA12, and a tandem structure SA13 according to the existing technique including a reflective metal electrode as the anode electrode. The x axis of the bar graph BC22 presents examples including a first single structure PD11, a second single structure PD12, and a tandem structure PD13 according to the embodiment of the present disclosure.

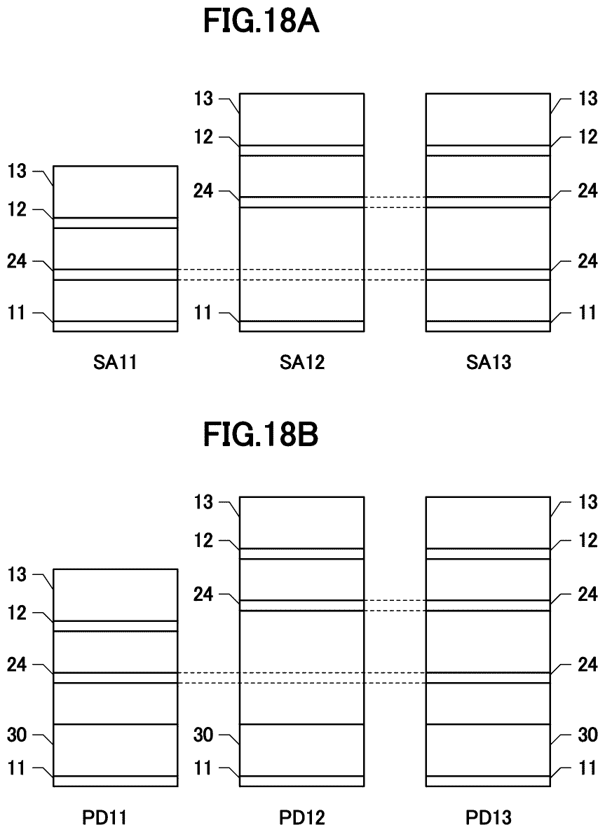

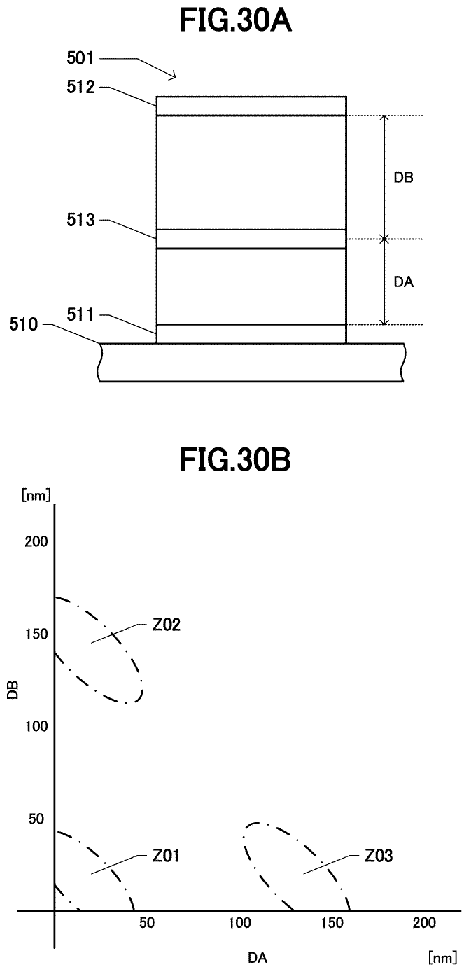

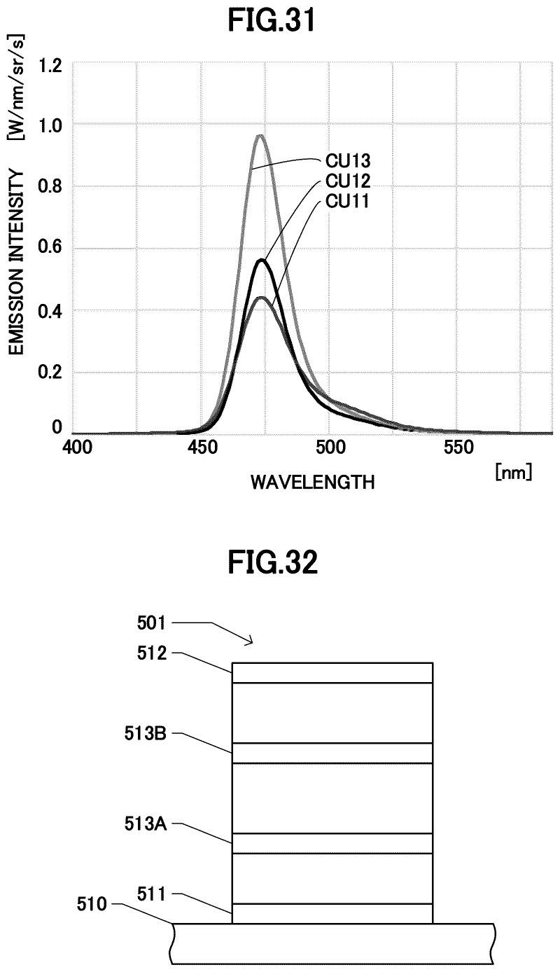

FIG. 18A illustrates exemplary comparative structures including the first single structure SA11, the second single structure SA12, and the tandem structure SA13 according to the existing technique including a reflective metal electrode as the anode electrode. The first single structure SA11 includes a single light-emitting layer 24 that applies the distances DA and DB corresponding to the zone Z01 illustrated in FIG. 30B as a first resonance condition. The second single structure SA12 includes a single light-emitting layer 24 that applies the distances DA and DB corresponding to the zone Z03 illustrated in FIG. 30B as a second resonance condition. The tandem structure SA13 includes two light-emitting layers 24, that is, a light-emitting layer 24 that applies the distances DA and DB corresponding to the zone Z03 illustrated in FIG. 30B as the second resonance condition and a light-emitting layer 24 that applies the distances DA and DB corresponding to the zone Z02 illustrated in FIG. 30B as a third resonance condition.

FIG. 18B illustrates exemplary structures including the first single structure PD11, the second single structure PD12, and the tandem structure PD13 according to the embodiment of the present disclosure. The first single structure PD11 is fabricated by adding the interference reflector 30 to the first single structure SA11 according to the existing technique, such that the interference reflector 30 is disposed between the anode electrode 11 and the light-emitting layer 24 in contact with the anode electrode 11. The second single structure PD12 is fabricated by adding the interference reflector 30 to the second single structure SA12 according to the existing technique, such that the interference reflector 30 is disposed between the anode electrode 11 and the light-emitting layer 24 in contact with the anode electrode 11. The tandem structure PD13 is fabricated by adding the interference reflector 30 to the tandem structure SA13 according to the existing technique, such that the interference reflector 30 is disposed between the anode electrode 11 and the lower light-emitting layer 24 in contact with the anode electrode 11.

The bar graphs BC21 and BC22 illustrated in FIG. 17 demonstrate the results provided by optical simulations in the present disclosure. The light emitted from a light-emitting element consists of an emitted light LE1, a loss DL1 caused by absorption by materials, a loss DL2 caused by optical confinement in organic layers, and an optical loss DL3.

As is represented by the bar graph BC21, the first single structure SA11 according to the existing technique exhibits an optical loss DL3 of almost 50%. The second single structure SA12 according to the existing technique exhibits an optical loss DL3 of approximately 15%. The tandem structure SA13 according to the existing technique exhibits an optical loss DL3 of approximately 30%. In contrast, as is represented by the bar graph BC22, the first single structure PD11 according to the embodiment of the present disclosure exhibits an optical loss DL3 of approximately 15%. The second single structure PD12 according to the embodiment of the present disclosure exhibits an optical loss DL3 of lower than 5%. The tandem structure PD13 according to the embodiment of the present disclosure exhibits an optical loss DL3 of lower than 10%. That is, the tandem structure PD13 according to the embodiment of the present disclosure, including the interference reflector 30, can reduce the optical loss DL3 and thus achieves significantly improved luminous efficiency.

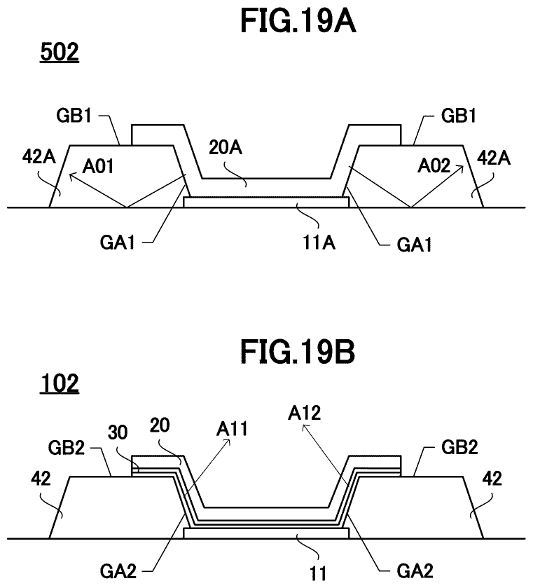

FIG. 19A illustrates an exemplary structure of a subpixel 502 corresponding to the technical features KA01 and KA03. This subpixel 502 includes a light-emitting mechanism 20A located not only above an anode electrode 11A but also above inclined portions GA1 of a pixel defining layer 42A and a part or all of ceiling portions GB1 of the pixel defining layer 42A. The light-emitting mechanism 20A is thus disposed in contact with the inclined portions GA1 of the pixel defining layer 42A and the part or all of the ceiling portions GB1 of the pixel defining layer 42A. The pixel defining layer 42A in FIG. 19A has a pixel opening through which a part of the anode electrode 11A corresponding to the subpixel 502 is exposed. This pixel opening of the pixel defining layer 42A is defined by the inclined portions GA1. FIG. 19A does not illustrate components, such as the cathode electrode and the capping layer.

The subpixel 502 corresponding to the technical feature KA01 includes an ITO layer serving as the anode electrode 11A, a dielectric mirror fabricated by stacking high refractive-index dielectric layers and low refractive-index dielectric layers on each other below the ITO layer, and a light reflecting layer below the dielectric mirror. The subpixel 502 corresponding to the technical feature KA03 includes the anode electrode 11A made of ITO, and a reflection mechanism fabricated by stacking high refractive-index copolymer layers and low refractive-index copolymer layers on each other at the lower portion on the rear side of the TFT substrate. In these subpixels 502, the reflection mechanism is not disposed above the inclined portions GA1 or the ceiling portions GB1 of the pixel defining layer 42A. This structure allows the light emitted from the light-emitting mechanism 20A to enter the pixel defining layer 42A through the inclined portions GA1 and the ceiling portions GB1 of the pixel defining layer 42A. For example, the light emitted from light-emitting mechanism 20A propagates through the inclined portions GA1 of the pixel defining layer 42A and dissipates in lateral directions parallel to the substrate surface, as indicated by the arrows A01 and A02 in FIG. 19A. This dissipation may lower the rate of light extraction from the subpixel 502, resulting in insufficient luminous efficiency. The dissipation may also be problematic in the existing technique SA01 including the reflective metal electrode as the anode electrode 11A.

FIG. 19B illustrates an exemplary structure of a subpixel 102 corresponding to the embodiment of the present disclosure. In the subpixel 102, a part or all of the organic compound layers including the light-emitting mechanism 20 and the interference reflector 30 is located not only above the anode electrode 11 but also above the inclined portions GA2 of the pixel defining layer 42 and a part or all of the ceiling portions GB2 of the pixel defining layer 42. The interference reflector 30 in this structure is disposed in contact with the inclined portions GA2 of the pixel defining layer 42 and the part or all of the ceiling portions GB2 of the pixel defining layer 42A. The pixel defining layer 42 in FIG. 19B has a pixel opening through which a part of the anode electrode 11 corresponding to the subpixel 102 is exposed. This pixel opening of the pixel defining layer 42 is defined by the inclined portions GA2. FIG. 19B does not illustrate components, such as the cathode electrode 12 and the capping layer 13.

In the subpixel 102, the interference reflector 30 is disposed between the anode electrode 11 and the light-emitting mechanism 20, and between the pixel defining layer 42 and the light-emitting mechanism 20. That is, the reflection mechanism made of the interference reflector 30 is disposed above the inclined portions GA2 and the part or all of the ceiling portions GB2 of the pixel defining layer 42. This structure causes the light emitted from the light-emitting mechanism 20 to be reflected by the interference reflector 30, without allowing the light to enter the pixel defining layer 42 through the inclined portions GA2 and the ceiling portions GB2 of the pixel defining layer 42. For example, the light emitted from the light-emitting mechanism 20 propagates upward to the light-emitting surface without passing through the inclined portions GA2 of the pixel defining layer 42, as indicated by the arrows A11 and A12 in FIG. 19B. This propagation increases the rate of light extraction from the subpixel 102, resulting in improved luminous efficiency.

In the subpixel 102, a part or all of the organic compound layers including the light-emitting mechanism 20 and the interference reflector 30 may be located, not above the ceiling portions GB2 of the pixel defining layer 42, but above the anode electrode 11 and the inclined portions GA2 of the pixel defining layer 42. The interference reflector 30 in this structure may adjoin the inclined portions GA2 of the pixel defining layer 42. That is, the part or all of the organic compound layers including the light-emitting mechanism 20 and the interference reflector 30 may be located not only above the anode electrode 11 but also above at least the inclined portions GA2 of the pixel defining layer 42.

### Embodiment 2

The following describes an organic light-emitting unit 2 configured as a type of bottom-emission OLED according to Embodiment 2. In the organic light-emitting unit 2 according to Embodiment 2, the component identical to that of the organic light-emitting unit 1 according to Embodiment 1 is provided with the same reference symbol.

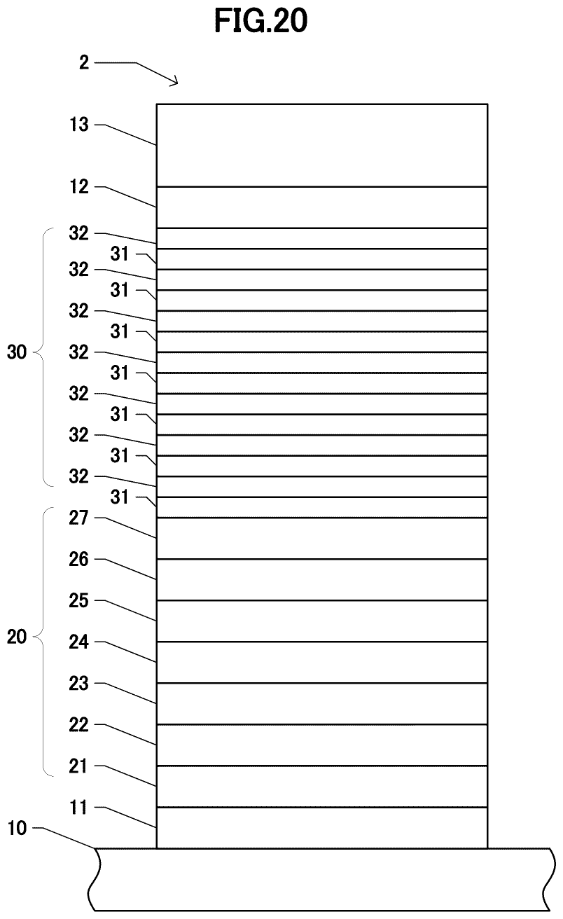

FIG. 20 is a schematic diagram illustrating an exemplary structure of the organic light-emitting unit 2 according to Embodiment 2. The organic light-emitting unit 2 includes an anode electrode 11 and a cathode electrode 12 opposed to each other on a circuit board 10. The organic light-emitting unit 2 also includes a light-emitting mechanism 20 and an interference reflector 30 disposed between the anode electrode 11 and the cathode electrode 12. The organic light-emitting unit 2 has a multilayer structure on the circuit board 10. The anode electrode 11 is a lower electrode serving as a first electrode in the organic light-emitting unit 2. The cathode electrode 12 is an upper electrode serving as a second electrode in the organic light-emitting unit 2. The anode electrode 11 is any electrode made of a translucent and semi-reflective material. The organic light-emitting unit 2 according to the embodiment does not require metallic reflection by the cathode electrode 12. The cathode electrode 12 may be an existing metal electrode provided that the interference reflector 30 has sufficient reflection properties. The light-emitting mechanism 20 has the same structure as that of the organic light-emitting unit 1 according to Embodiment 1, except for that the hole injection layer 21 of the light-emitting mechanism 20 of the organic light-emitting unit 2 is disposed in contact with the anode electrode 11.

The interference reflector 30 illustrated in FIG. 20 is disposed, between the cathode electrode 12 and the light-emitting layer 24, in contact with the cathode electrode 12. The p-type low refractive-index layers 31 and the n-type high refractive-index layers 32 of the interference reflector 30 each have an optimum film thickness for the wavelength of the color of emitted light. The interference reflector 30 of the organic light-emitting unit 2 illustrated in FIG. 20 adjoins the electron injection layer 27.

The anode electrode 11 of the organic light-emitting unit 2 serves as a first reflection surface. The interference reflector 30 includes multiple second reflection surfaces defined by the interfaces between the p-type low refractive-index layers 31 and the n-type high refractive-index layers 32. The light emitted from the light-emitting layer 24 and the light reflected by the anode electrode 11 are reflected at a predetermined reflection factor, when propagating from the light-emitting mechanism 20 into one of the p-type low refractive-index layers 31, or propagating from one of the n-type high refractive-index layers 32 into one of the p-type low refractive-index layers 31. The interference reflector 30 preferably includes at least seven pairs of the p-type low refractive-index layers 31 and the n-type high refractive-index layers 32. The interference reflector 30 illustrated in FIG. 20 includes seven pairs of the p-type low refractive-index layers 31 and the n-type high refractive-index layers 32. In this interference reflector 30 of the organic light-emitting unit 2, seven p-type low refractive-index layers 31 having a p-type of conductivity and a low refractive index, as the first charge generating layers having a first type of conductivity, and a first refractive index, and seven n-type high refractive-index layers 32 having an n-type of conductivity and a high refractive index, as the second charge generating layers having a second type of conductivity and a second refractive index, are alternately stacked on each other.

The organic light-emitting unit 2, including the interference reflector 30, can also significantly reduce the ratio of the optical loss DL3 compared to the existing structure SA01, like the structure PD01 according to the embodiment represented by the bar graph BC10 illustrated in FIG. 10. The organic light-emitting unit 2 can therefore achieve significantly improved luminous efficiency.

Alternatively, the interference reflector 30 of the organic light-emitting unit 2 may include n-type low refractive-index layers 33 having an n-type of conductivity and a low refractive index as the first charge generating layers having a first type of conductivity and a first refractive index, and p-type high refractive-index layers 34 having a p-type of conductivity and a high refractive index as the second charge generating layers having a second type of conductivity and a second refractive index. The n-type low refractive-index layers 33 and the p-type high refractive-index layers 34 may be alternately stacked on each other. The interference reflector 30 of the organic light-emitting unit 2 in this modification is disposed, between the cathode electrode 12 and the light-emitting layer 24, in contact with the cathode electrode 12.

Alternatively, the light-emitting mechanism 20 of the organic light-emitting unit 2 may have a tandem structure including two layer groups each including the hole transport layer 22 to the electron transport layer 26, between the hole injection layer 21 and the electron injection layer 27. This tandem structure further includes, between the first layer group including the hole transport layer 22 to the electron transport layer 26 and the second layer group including the hole transport layer 22 to the electron transport layer 26, an n-type charge generating layer 28 and a p-type charge generating layer 29. The interference reflector 30 of the organic light-emitting unit 2 in this modification is disposed, between the cathode electrode 12 and the upper light-emitting layer 24, in contact with the cathode electrode 12.

The organic light-emitting unit 2 in the modifications, including the interference reflector 30, can also significantly reduce the ratio of optical loss. The organic light-emitting unit 2 can therefore achieve significantly improved luminous efficiency. The organic light-emitting unit 2, if provided with a microlens array as an external or internal structure according to a light extraction technique, can efficiently extract light, thereby achieving further improved luminous efficiency.

### Embodiment 3

The following describes an organic light-emitting unit 3 according to Embodiment 3 that includes a modified interference reflector 30. In the organic light-emitting unit 3 according to Embodiment 3, the component identical to that according to the above embodiments is provided with the same reference symbol.

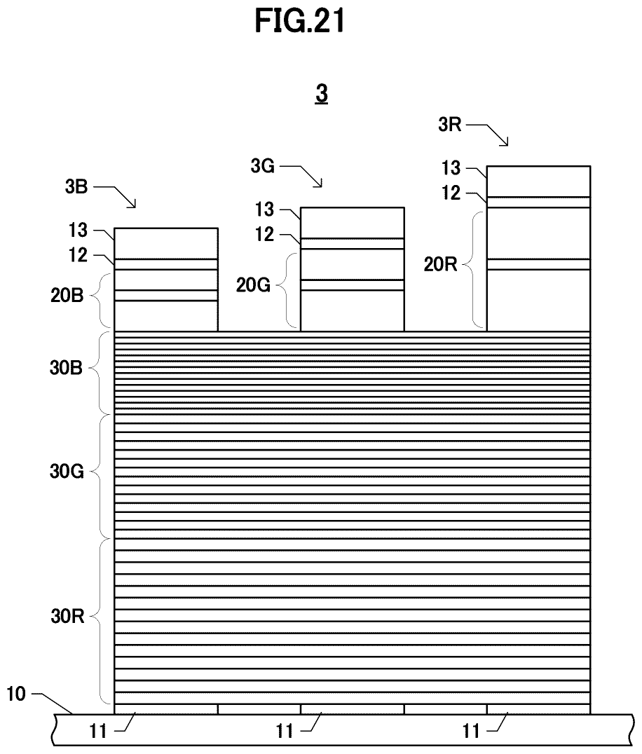

FIG. 21 is a schematic diagram illustrating an exemplary structure of an organic light-emitting unit 3 according to Embodiment 3 including light-emitting subunits of three primary colors, that is, a red light-emitting unit 3R, a green light-emitting unit 3G, and a blue light-emitting unit 3B. The red light-emitting unit 3R includes a light-emitting mechanism 20R including a light-emitting layer 24 exhibiting a red visible light spectrum, which corresponds to the light-emitting mechanism 20 according to the above embodiments. The green light-emitting unit 3G includes a light-emitting mechanism 20G including a light-emitting layer 24 exhibiting a green visible light spectrum, which corresponds to the light-emitting mechanism 20 according to the above embodiments. The blue light-emitting unit 3B includes a light-emitting mechanism 20B including a light-emitting layer 24 exhibiting a blue visible light spectrum, which corresponds to the light-emitting mechanism 20 according to the above embodiments.

Each of the red light-emitting unit 3R, the green light-emitting unit 3G, and the blue light-emitting unit 3B includes an anode electrode 11 and a cathode electrode 12 opposed to each other on a circuit board 10. The red light-emitting unit 3R includes the light-emitting mechanism 20R between the anode electrode 11 and the cathode electrode 12. The green light-emitting unit 3G includes the light-emitting mechanism 20G between the anode electrode 11 and the cathode electrode 12. The blue light-emitting unit 3B includes the light-emitting mechanism 20B between the anode electrode 11 and the cathode electrode 12.

The red light-emitting unit 3R, the green light-emitting unit 3G, and the blue light-emitting unit 3B illustrated in FIG. 21 include common interference reflectors 30R, 30G, and 30B between the anode electrode 11 and the cathode electrode 12. The interference reflector 30R illustrated in FIG. 21, serving as a first interference reflector segment, is stacked on and in contact with the anode electrodes 11 of the red light-emitting unit 3R, the green light-emitting unit 3G, and the blue light-emitting unit 3B. The interference reflector 30R includes p-type low refractive-index layers 31 and n-type high refractive-index layers 32 each having a refractive index and a film thickness defined in accordance with the red visible light spectrum. The interference reflector 30G illustrated in FIG. 21, serving as a second interference reflector segment, is stacked on the interference reflector 30R. The interference reflector 30G includes p-type low refractive-index layers 31 and n-type high refractive-index layers 32 each having a refractive index and a film thickness defined in accordance with the green visible light spectrum. The interference reflector 30B illustrated in FIG. 21, serving as a third interference reflector segment, is stacked on the interference reflector 30G in contact with the hole injection layer 21. The interference reflector 30B includes p-type low refractive-index layers 31 and n-type high refractive-index layers 32 each having a refractive index and a film thickness defined in accordance with the blue visible light spectrum. As described above, the organic light-emitting unit 3 illustrated in FIG. 21 includes the interference reflectors 30R, 30G, and 30B sequentially stacked in the vertical direction corresponding to the film thickness direction. The interference reflectors 30R, 30G, and 30B satisfy the reflection conditions of the visible light spectra associated with the individual luminescent colors of red, green, and blue.

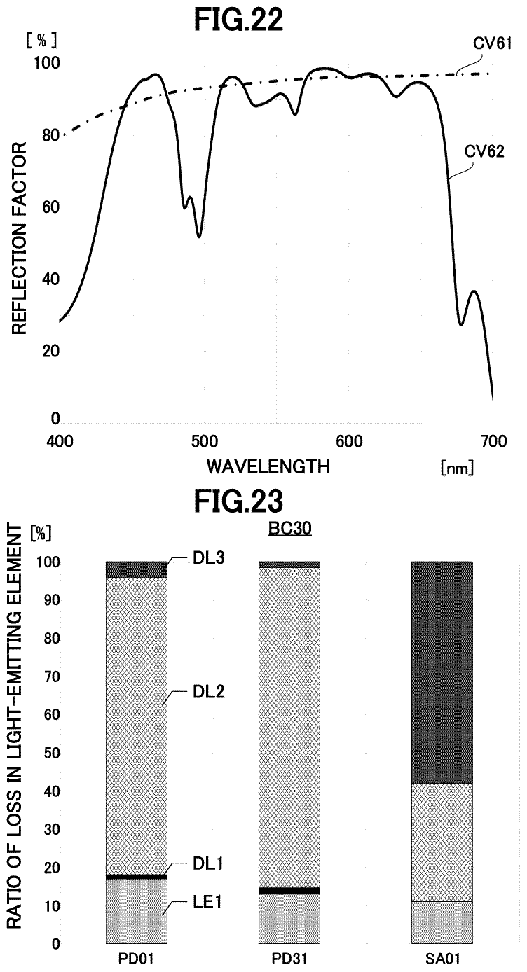

FIG. 22 is a curve graph illustrating parameters including a reflection factor in the organic light-emitting unit 3 including the interference reflectors 30R, 30G, and 30B. The curve CV61 in the curve graph illustrated in FIG. 22 represents a reflection factor of an electrode having a two-layer structure of ITO/Ag fabricated by combining a thin silver film with an ITO film. The curve CV62 represents a reflection factor of the interference reflectors 30R, 30G, and 30B included in the organic light-emitting unit 3. The organic light-emitting unit 3, including the interference reflectors 30R, 30G, and 30B, can appropriately reflect and output the emitted light of red, green, and blue. The organic light-emitting unit 3 does not require a reflective electrode made of metal films and thus reduces optical loss, thereby achieving improved luminous efficiency.

FIG. 23 illustrates a bar graph BC30 for comparison of the percentages of losses in the organic light-emitting unit 3. The x axis of the bar graph BC30 presents the structure PD01 including the organic light-emitting unit 1 according to Embodiment 1 accompanied by comparative examples including a structure PD31 including the organic light-emitting unit 3 according to Embodiment 3 and the existing structure SA01 including a reflective metal electrode as the anode electrode. The bar graph BC30 demonstrates the results provided by optical simulations in the present disclosure. The light emitted from a light-emitting element consists of an emitted light LE1, a loss DL1 caused by absorption by materials, a loss DL2 caused by optical confinement in organic layers, and an optical loss DL3.

The organic light-emitting unit 3 can further reduce the ratio of the optical loss DL3 compared to the structure PD01 according to Embodiment 1, which can significantly reduce the ratio of the optical loss DL3 compared to the existing structure SA01. The organic light-emitting unit 3 according to Embodiment 3, including the sequentially stacked interference reflectors 30R, 30G, and 30B, can further reduce the optical loss DL3, thereby achieving significantly improved luminous efficiency. The organic light-emitting unit 3, if provided with a microlens array as an external or internal structure according to a light extraction technique, can efficiently extract light, thereby achieving further improved luminous efficiency.

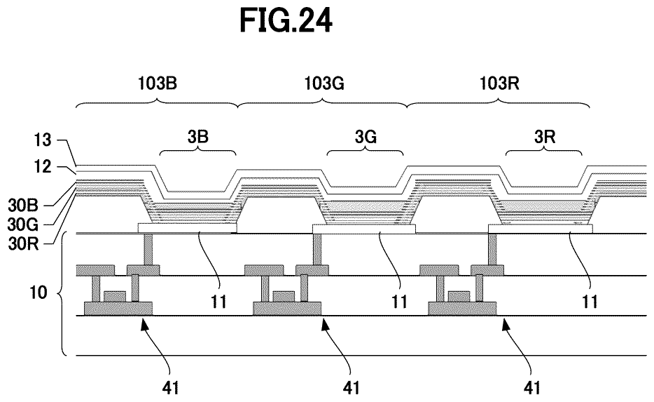

FIG. 24 is a sectional view of the red light-emitting unit 3R, the green light-emitting unit 3G, and the blue light-emitting unit 3B, or light-emitting subunits of three primary colors, and driving TFTs 41 for driving the individual light-emitting units. The red light-emitting unit 3R, the green light-emitting unit 3G, and the blue light-emitting unit 3B illustrated in FIG. 24 are included in the organic light-emitting unit 3 according to Embodiment 3. The driving TFTs 41 illustrated in FIG. 24 operate like those illustrated in FIG. 5. FIG. 24 also illustrates a pixel defining layer (PDL) 42 identical to that in FIG. 5.

The red light-emitting unit 3R, the driving TFT 41 provided in association therewith, a switching TFT fed with scan signals at the gate electrode, and a pixel circuit having a storage capacitor for retaining a pixel signal constitute a red light-emitting subpixel 103R that emits red light. The green light-emitting unit 3G, the driving TFT 41 provided in association therewith, a switching TFT, and a pixel circuit having a storage capacitor constitute a green light-emitting subpixel 103G that emits green light. The blue light-emitting unit 3B, the driving TFT 41 provided in association therewith, a switching TFT, and a pixel circuit having a storage capacitor constitute a blue light-emitting subpixel 103B that emits blue light.

The structure illustrated in FIG. 24 includes the light-emitting layer 24 exhibiting a red visible light spectrum in the red light-emitting unit 3R, the light-emitting layer 24 exhibiting a green visible light spectrum in the green light-emitting unit 3G, and the light-emitting layer 24 exhibiting a blue visible light spectrum in the blue light-emitting unit 3B, between the anode electrode 11 and the cathode electrode 12. The organic light-emitting unit 3 is entirely provided with the interference reflector 30R for the visible light spectrum of red as an exemplary first color on and in contact with the anode electrode 11. The interference reflector 30R is provided with the interference reflector 30G thereon for the visible light spectrum of green as an exemplary second color. The interference reflector 30G is provided with the interference reflector 30B thereon for the visible light spectrum of blue as an exemplary third color. The first to third colors may be any combination of colors having mutually different emission wavelengths.

Alternatively, all or some of the interference reflectors 30R, 30G, and 30B of the organic light-emitting unit 3 may include n-type low refractive-index layers 33 having an n-type of conductivity and a low refractive index as the first charge generating layers having a first type of conductivity and a first refractive index, and p-type high refractive-index layers 34 having a p-type of conductivity and a high refractive index as the second charge generating layers having a second type of conductivity and a second refractive index. The n-type low refractive-index layers 33 and the p-type high refractive-index layers 34 may be alternately stacked on each other. The interference reflector 30R of the organic light-emitting unit 3 in this modification is disposed, between the anode electrode 11 and the light-emitting layer 24, on and in contact with the anode electrode 11. The interference reflector 30G of the organic light-emitting unit 3 is disposed, between the anode electrode 11 and the light-emitting layer 24, on the interference reflector 30R. The interference reflector 30B of the organic light-emitting unit 3 is disposed, between the anode electrode 11 and the light-emitting layer 24, on the interference reflector 30G.

Alternatively, all or some of the light-emitting mechanism 20R of the red light-emitting unit 3R, the light-emitting mechanism 20G of the green light-emitting unit 3G, the light-emitting mechanism 20B of the blue light-emitting unit 3B in the organic light-emitting unit 3 may have a tandem structure including two layer groups each including the hole transport layer 22 to the electron transport layer 26, between the hole injection layer 21 and the electron injection layer 27. This tandem structure further includes, between the first layer group including the hole transport layer 22 to the electron transport layer 26 and the second layer group including the hole transport layer 22 to the electron transport layer 26, an n-type charge generating layer 28 and a p-type charge generating layer 29. The interference reflector 30R of the organic light-emitting unit 3 in this modification is disposed, between the anode electrode 11 and the light-emitting layer 24, on and in contact with the anode electrode 11. The interference reflector 30G of the organic light-emitting unit 3 is disposed, between the anode electrode 11 and the light-emitting layer 24, on the interference reflector 30R. The interference reflector 30B of the organic light-emitting unit 3 is disposed, between the anode electrode 11 and the light-emitting layer 24, on the interference reflector 30G.

The organic light-emitting unit 3 may also be configured as a type of bottom-emission OLED. The interference reflector 30R of the organic light-emitting unit 3 in this modification is disposed, between the cathode electrode 12 and the light-emitting layer 24, below and in contact with the cathode electrode 12. The interference reflector 30G of the organic light-emitting unit 3 is disposed, between the cathode electrode 12 and the light-emitting layer 24, below the interference reflector 30R. The interference reflector 30B of the organic light-emitting unit 3 is disposed, between the cathode electrode 12 and the light-emitting layer 24, below the interference reflector 30G and in contact with the electron injection layer 27.

### Embodiment 4

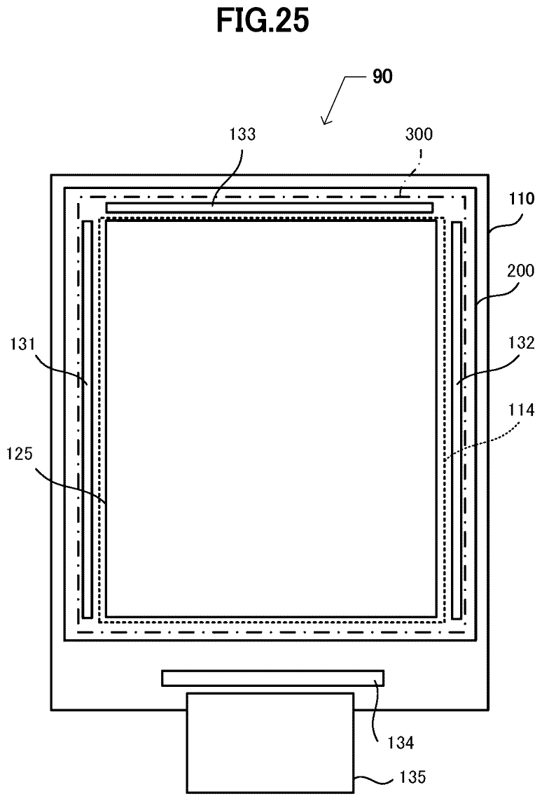

The following describes a display device 90 according to Embodiment 4 that includes the organic light-emitting unit according to any of the above embodiments. FIG. 25 is a schematic diagram illustrating an exemplary structure of the display device 90 according to the embodiment.

The display device 90 includes a TFT substrate 110 identical to the circuit board 10, a sealing substrate 200, and a bonding segment (glass frit seal) 300. The TFT substrate 110 is provided with any of the organic light-emitting units 1 to 3 thereon as OLED elements. The sealing substrate 200 faces the TFT substrate 110. The bonding segment 300 is disposed between the TFT substrate 110 and the sealing substrate 200, and thus bonds the TFT substrate 110 and the sealing substrate 200 to each other and tightly encloses the OLED elements.

The TFT substrate 110 has a display region 125 and a cathode electrode region 114 therearound. The TFT substrate 110 is provided with a scan driver 131, an emission driver 132, a protection circuit 133, and a driver integrated circuit (IC) 134 around the cathode electrode region 114. These components are connected to an external device via a flexible printed circuit (FPC) 135.

The scan driver 131 drives the scanning lines of the TFT substrate 110. The emission driver 132 drives the emission control lines and controls the light emission periods of the individual subpixels. The driver IC 134 is implemented by an anisotropic conductive film (ACF), for example.

The driver IC 134 provides the scan driver 131 and the emission driver 132 with power and timing (control) signals, and provides the data lines with data voltage corresponding to image data. That is, the driver IC 134 has a function of display control.

The sealing substrate 200 is a transparent insulating substrate, such as glass substrate, for example. The light-emitting surface (front surface) of the sealing substrate 200 is provided with a λ/4 retardation film and a polarizing plate to reduce reflection of light incident from the outside.

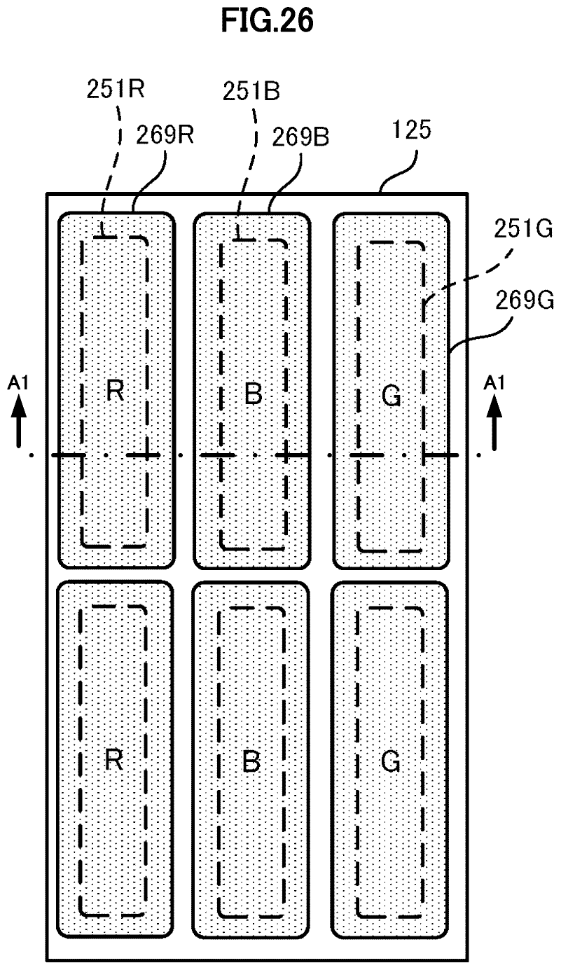

FIG. 26 is a plan view of a part of the display region 125. The display region 125 encompasses multiple subpixels. FIG. 26 illustrates some of the subpixels arranged in matrix within the display region 125. At least three subpixels emit light having mutually different colors of first to third colors. The first color is typically blue, the second color is typically red, and the third color is typically green, for example. FIG. 26 illustrates red subpixels (light-emitting regions) 251R, blue subpixels (light-emitting regions) 251B, and green subpixels (light-emitting regions) 251G. The sectional view taken along the line A1-A1 of FIG. 26 corresponds to that illustrated in FIG. 5 or 24. The subpixels emitting light of first to third colors are not necessarily arranged in a stripe array like that illustrated in FIG. 24.

Each of the subpixels (light-emitting regions) illustrated in FIG. 26 is entirely covered with an organic light-emitting layer of the same color. Specifically, the red subpixel 251R, the blue subpixel 251B, and the green subpixel 251G are completely covered with a red organic light-emitting layer 269R, a blue organic light-emitting layer 269B, and a green organic light-emitting layer 269G, respectively. FIG. 26 illustrates representative ones of the red, blue, and green subpixels accompanying reference symbols. Each subpixel emits light having any color of red, blue, and green. The red, blue, and green subpixels constitute a single pixel (primary pixel).

The subpixels in the embodiment are made of any of the organic light-emitting units 1 to 3 according to Embodiments 1 to 3. The subpixels can therefore achieve improved luminous efficiency, because of the effects of any of the structures in Embodiments 1 to 3.

### Embodiment 5

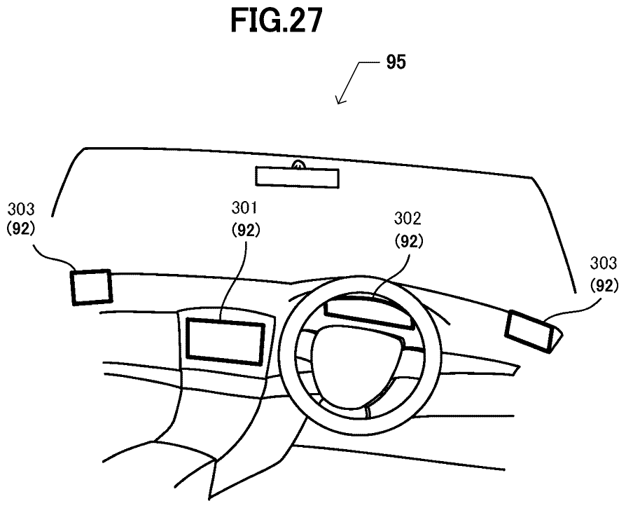

The following describes an in-vehicle display 92 according to Embodiment 5 that includes the display device 90 according to Embodiment 4. FIG. 27 is a schematic diagram illustrating the in-vehicle displays 92 according to the embodiment and a vehicle 95 including these in-vehicle displays 92.

The in-vehicle displays 92 are installed inside an automobile as the vehicle 95 illustrated in FIG. 27, and display various types of information. Examples of the in-vehicle displays 92 include a center information display (CID) 301, a cluster display 302, and lateral displays 303 illustrated in FIG. 27. The CID 301, the cluster display 302, and the lateral displays 303 according to the embodiment can be implemented by the display device 90.

The CID 301 is mounted at the center of the dashboard of the vehicle 95, and displays information provided from systems, such as an audio system, a navigation system, and a system for managing vehicle states. The cluster display 302 displays a speedometer and other indicators. The lateral displays 303 are mounted on the left and right sides of the dashboard and display images captured by cameras, thereby functioning as sideview mirrors.

These in-vehicle displays 92 inside the vehicle 95 may suffer from insufficient visibility of the screens due to sunlight or other factors. The in-vehicle displays 92 are implemented by the display device 90 including any of the organic light-emitting units 1 to 3, and thus achieve improved luminous efficiency. The screens of the in-vehicle displays 92 can therefore enable preferable display with enhanced visibility regardless of sunlight.

The in-vehicle displays 92 are not necessarily the CID 301, the cluster display 302, and the lateral displays 303, and may also be any display installed inside a vehicle. The display device 90 is not necessarily applied as the in-vehicle display 92, and may also be mounted on any industrial transport equipment.

### Embodiment 6

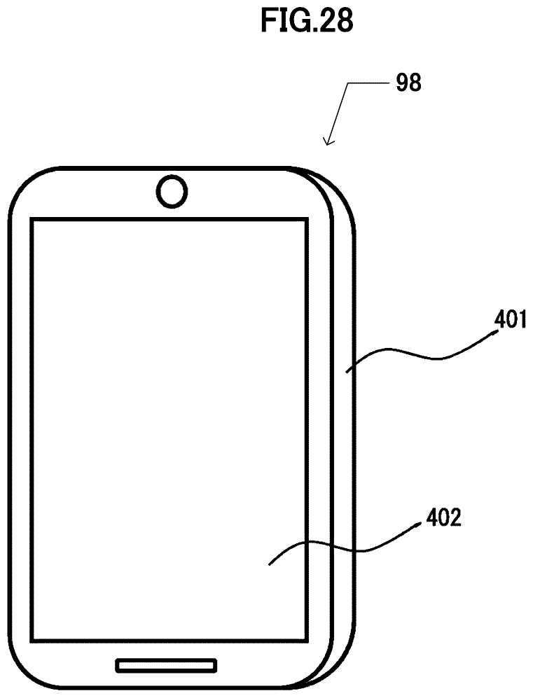

The following describes a smartphone 98 according to Embodiment 6, as an electronic device including the display device 90 according to Embodiment 4. FIG. 28 is a perspective view of an exemplary structure of the smartphone 98 as the electronic device. The smartphone 98 includes a housing 401, the display device 90 according to Embodiment 4 inside the housing 401, and a cover glass 402 mounted on the screen side of the display device 90. The housing 401 also accommodates some units having functions required for smartphones. Examples of the units include transmitting and receiving units, various controllers, storages, audio units including a speaker and a microphone, and a battery.

The smartphone 98 is sometimes used in bright environments, such as outdoors. The smartphone 98 includes the display device 90, and can thus achieve improved luminous efficiency. The screen of the smartphone 98 can therefore enable preferable display with enhanced visibility even in bright environments.

The display device 90 is not necessarily applied to the smartphone 98 as the electronic device. For example, the display device 90 may also be applied to personal computers, personal digital assistances (PDAs), tablets, head mounted displays, projectors, and digital (video) cameras.

The above-described embodiments may be modified in various manners within the gist of the present disclosure. For example, the sealing structure including the sealing layer 51 illustrated in FIG. 8A or 8B or the sealing structure including the sealing substrate 200 and the bonding segment 300 illustrated in FIG. 25 may be replaced with any of various structures in view of the characteristics of the device.

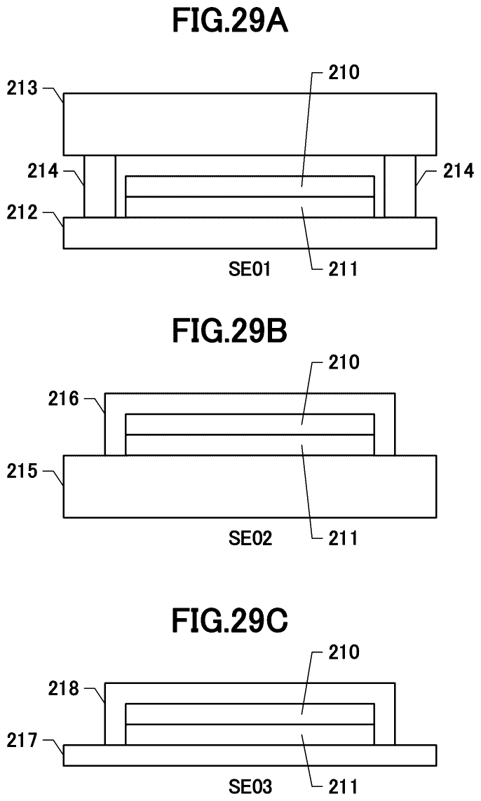

FIGS. 29A to 29C are each a sectional view of an exemplary sealing structure of the organic light-emitting unit according to any of the above embodiments. FIG. 29A illustrates a first sealing structure SE01 including two glass substrates. FIG. 29B illustrates a second sealing structure SE02 including a glass substrate and a thin film encapsulation (TFE) layer. FIG. 29C illustrates a third sealing structure SE03 including a polyimide (PI) substrate and a TFE layer.

The first sealing structure SE01 tightly encloses organic light-emitting units 210 and a TFT substrate 211 functioning as the circuit board, using a first glass substrate 212, a second glass substrate 213, and glass frit segments 214. The first glass substrate 212 has a thickness of 0.2 to 0.25 mm, for example. The second glass substrate 213 has a thickness of 0.4 to 0.5 mm, for example. The glass frit segments 214 are disposed between the first glass substrate 212 and the second glass substrate 213, bond the first glass substrate 212 and the second glass substrate 213 to each other, and enclose the organic light-emitting units 210 and the TFT substrate 211. The first sealing structure SE01 is less susceptible to external environments, such as water, and enables the best color reproducibility, but suffers from a large thickness and weight.

The second sealing structure SE02 tightly encloses the organic light-emitting units 210 and the TFT substrate 211, using a glass substrate 215 and a TFE layer 216. The glass substrate 215 has a thickness of 0.4 to 0.5 mm, for example. The TFE layer 216 has a thickness of 20 μm, for example. The TFE layer 216 covers the tops of the organic light-emitting units 210 and the TFT substrate 211 and is bonded to the glass substrate 215 at the edges of the organic light-emitting units 210 and the TFT substrate 211, and thus tightly encloses the organic light-emitting units 210 and the TFT substrate 211. The second sealing structure SE02 has more preferable properties than the first sealing structure SE01 in terms of thickness, form factor, safety, and weight. The second sealing structure SE02 exhibits the best integration of functions.

The third sealing structure SE03 tightly encloses the organic light-emitting units 210 and the TFT substrate 211, using a polyimide layer 217 and a TFE layer 218. The polyimide layer 217 has a thickness of 20 μm, for example. The TFE layer 218 has a thickness of 20 μm, for example. The TFE layer 218 covers the tops of the organic light-emitting units 210 and the TFT substrate 211 and is bonded to the polyimide layer 217 at the edges of the organic light-emitting units 210 and the TFT substrate 211, and thus tightly encloses the organic light-emitting units 210 and the TFT substrate 211. The third sealing structure SE03 has more preferable properties than the first sealing structure SE01 and the second sealing structure SE02 in terms of weight. The third sealing structure SE03 exhibits the best properties in terms of thickness, form factor, safety, and integration of functions.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

1. An organic light-emitting unit, comprising:
a first electrode and a second electrode opposed to each other; and
organic compound layers disposed between the first electrode and the second electrode, and including at least a light-emitting layer and an interference reflector, wherein
the interference reflector
includes first charge generating layers having a first type of conductivity and a first refractive index and second charge generating layers having a second type of conductivity and a second refractive index, the first charge generating layers and the second charge generating layers being alternately stacked on each other, and
is disposed in contact with the first electrode or the second electrode.

2. The organic light-emitting unit according to claim 1, wherein
each of the first charge generating layers is a first organic material layer having electron acceptability, the first organic material layer being fabricated by doping a charge transport material with impurities having the first type of conductivity, and
each of the second charge generating layers is a second organic material layer having electron-donating ability, the second organic material layer being fabricated by doping a charge transport material with impurities having the second type of conductivity.

3. The organic light-emitting unit according to claim 1, further comprising
a hole injection layer, a hole transport layer, an electron injection layer, and an electron transport layer, between the first electrode and the second electrode, wherein
the interference reflector is located at a position different from the hole injection layer, the hole transport layer, the electron injection layer, and the electron transport layer.

4. The organic light-emitting unit according to claim 3, wherein the interference reflector is disposed in contact with the hole injection layer or the electron injection layer.

5. The organic light-emitting unit according to claim 1, wherein
the light-emitting layer includes
a first light-emitting layer segment disposed in a first region and exhibiting a visible light spectrum of a first color,
a second light-emitting layer segment disposed in a second region and exhibiting a visible light spectrum of a second color having a different emission wavelength from the first color, and
a third light-emitting layer segment disposed in a third region and exhibiting a visible light spectrum of a third color having a different emission wavelength from the first color and the second color, and
the interference reflector includes
a first interference reflector segment disposed in the first region in contact with the first electrode or the second electrode, the first interference reflector segment being designed for the visible light spectrum of the first color,
a second interference reflector segment disposed in the second region in contact with the first electrode or the second electrode, the second interference reflector segment being designed for the visible light spectrum of the second color, and
a third interference reflector segment disposed in the third region in contact with the first electrode or the second electrode, the third interference reflector segment being designed for the visible light spectrum of the third color.

6. The organic light-emitting unit according to claim 1, wherein
the light-emitting layer includes
a first light-emitting layer segment disposed in a first region and exhibiting a visible light spectrum of a first color,
a second light-emitting layer segment disposed in a second region and exhibiting a visible light spectrum of a second color having a different emission wavelength from the first color, and
a third light-emitting layer segment disposed in a third region and exhibiting a visible light spectrum of a third color having a different emission wavelength from the first color and the second color, and
the interference reflector includes
a first interference reflector segment disposed in contact with the first electrode or the second electrode, the first interference reflector segment being designed for the visible light spectrum of the first color,
a second interference reflector segment disposed in contact with the first interference reflector segment, the second interference reflector segment being designed for the visible light spectrum of the second color, and
a third interference reflector segment disposed in contact with the second interference reflector segment, the third interference reflector segment being designed for the visible light spectrum of the third color.

7. The organic light-emitting unit according to claim 1, further comprising:
a light extraction layer disposed on an outer side of the first electrode and the second electrode, wherein
the light extraction layer includes
a high refractive-index portion overlapping with the light-emitting layer in a direction perpendicular to a plane of the light-emitting layer, and
a low refractive-index portion not overlapping with the light-emitting layer in the direction perpendicular to the plane of the light-emitting layer, and
the low refractive-index portion has a thickness gradually decreasing in a direction from a side farther from the light-emitting layer to a side closer to the light-emitting layer, and thus defines a curved edge, the direction being parallel to the plane of the light-emitting layer.

8. The organic light-emitting unit according to claim 1, wherein the first electrode, the second electrode, the light-emitting layer, and the interference reflector are formed as a microlens array including locally maximum portions, inclined portions, and locally minimum portions.

9. The organic light-emitting unit according to claim 1, wherein
a part or all of the organic compound layers is disposed above inclined portions of a pixel defining layer, and
the interference reflector is disposed in contact with the inclined portions of the pixel defining layer.

10. A display device, comprising the organic light-emitting unit according to claim 1.

11. An in-vehicle display, comprising the display device according to claim 10.

12. An electronic device, comprising the display device according to claim 10.

13. A vehicle, comprising the in-vehicle display according to claim 11.
